(19) United States
(12) Patent Application Publication
(10) Pub. No.: US 2011/0186102 A1
(43) Pub. Date: Aug. 4, 2011

(54) PHOTOELECTRIC CONVERSION ELEMENT, THIN-FILM SOLAR CELL, AND PHOTOELECTRIC CONVERSION ELEMENT MANUFACTURING METHOD

(75) Inventors: Hiroyuki KOBAYASHI, Kanagawa (JP); Shinya SUZUKI, Kanagawa (JP); Toshiaki FUKUNAGA, Kanagawa (JP)

(73) Assignee: FUJIFILM CORPORATION, Tokyo (JP)

(21) Appl. No.: 13/017,939

(22) Filed: Jan. 31, 2011

(30) Foreign Application Priority Data
Feb. 1, 2010 (JP) 2010-020214
Jan. 18, 2011 (JP) 2011-007765

(51) Int. Cl. H01L 31/02; H01L 31/18; H01L 31/042

(52) U.S. Cl. 136/244; 438/93; 136/256; 257/E31.001

(57) ABSTRACT

A photoelectric conversion element includes a substrate with an insulation layer having a metallic substrate and an electrical insulation layer formed on a surface of the metallic substrate, a diffusion prevention layer made of nitride and formed on the electrical insulation layer, an alkali supply layer containing an alkali metal element and formed on the diffusion prevention layer, a lower electrode formed on the alkali supply layer, a photoelectric conversion layer including a compound semiconductor layer and formed on the lower electrode, and an upper electrode formed on the photoelectric conversion layer. The electrical insulation layer includes an anodized film of aluminum, and the diffusion prevention layer prevents at least diffusion of the alkali metal element from the alkali supply layer to the substrate with the insulation layer.

### BACKGROUND OF THE INVENTION

The present invention relates to a flexible photoelectric conversion element having excellent withstand voltage characteristics and a high conversion efficiency, to a thin-film solar cell using the photoelectric conversion element, and to a photoelectric conversion element manufacturing method for manufacturing the photoelectric conversion element.

The substrates mainly used for thin-film solar cells are glass substrates. The glass substrate, however, breaks easily, requiring adequate care during handling, and has a limited application range owing to its lack of flexibility. Recently, solar cells are attracting attention as a power source for buildings such as residential housing. While increases in the solar cell size are essential for ensuring an adequate power supply, reductions in substrate weight have been desired with the increases in the solar cell surface area.

Nevertheless, when the glass substrate is made thinner in an attempt to reduce the substrate weight, the glass breaks more readily, resulting in demands for a substrate material that is shatterproof, flexible, and lighter than a glass substrate.

Additionally, the price of the glass substrate is relatively high compared to the price of a photoelectric conversion layer material of a solar cell, and thus an inexpensive substrate material that promotes more widespread use of solar cells is desired. When such a substrate material employs metal, difficulties arise in insulating the area between the substrate and solar cell material placed thereon. When resin is employed, the problem arises that the substrate cannot withstand high temperatures, such as the temperatures exceeding 400° C. that are required for solar cell formation.

That is, a glass substrate made of soda-lime glass, for example, exhibits adequate insulation properties but fails to achieve flexibility and low weight, and a metal substrate exhibits excellent flexibility and low weight, but fails to achieve adequate insulation properties. This makes it difficult to develop a substrate that offers insulation properties, flexibility, as well as low weight.

On the other hand, a copper-indium-gallium-selenide (CIGS) solar cell has been known to improve power generation efficiency when sodium (Na; sodium ion: Na⁺) is diffused into the light absorbing layer (photoelectric conversion layer). In prior art, soda-lime glass is used as the substrate so that the Na contained in the soda-lime glass is diffused into the light absorbing layer.

However, when a metal sheet other than soda-lime glass is used as the substrate of the solar panel, the problem of having to supply Na separately to the light absorbing layer arises in addition to the above-described problem with insulation properties. For example, in JP 10-74966 A (Patent Document 1) and JP 10-74967 A (Patent Document 2), JP 9-55378 A (Patent Document 3), and JP 10-125941 A (Patent Document 4), Na₂Se, Na₂O, and Na₂S are respectively mixed vapor deposited. In JP 2005-117012 A (Patent Document 5), sodium phosphate is vapor-deposited on molybdenum (Mo). In JP 2006-210424 A (Patent Document 6), an aqueous solution containing sodium molybdate is deposited on a precursor. In JP 2003-318424 A (Patent Document 7), Na₂S and Na₂Se are formed to supply Na and, in JP 2005-86167 A (Patent Document 8), Na₃AlF₆ is formed between Mo and the substrate and/or the light absorbing layer to supply Na. In JP 8-222750 A (Patent Document 9), Na₂S or Na₂Se is precipitated onto Mo electrodes, and in JP 2004-158556 A (Patent Document 10) and JP 2004-79858 A (Patent Document 11), NaF is coated on Mo to supply Na.

Additionally, in JP 2006-80370 A (Patent Document 12), when a metal substrate is used as a substrate for a solar cell using a chalcopyrite semiconductor, a glass layer is formed on the metal substrate as an insulation layer between the metal substrate and photoelectric conversion layer, thereby increasing the withstand voltage of the substrate and providing the substrate at low cost.

In JP 2009-267332 A (Patent Document 13), a first insulating oxide film is formed on a material substrate by anodizing, and a second insulating film that contains alkali metal ions is formed on this first insulating oxide film to form the solar cell substrate.

In JP 4022577 B (Patent Document 14), when a solar cell comprising a chalcopyrite absorbing layer is formed on a glass substrate, an alkali metal element selected from Na, K, and Li, or a compound thereof, is added by doping before or during the manufacture of the absorbing layer. Then, by a diffusion intercepting layer that is selected from TiN, Al₂O₃, SiO₂, Si₃N₄, ZrO₂, or TiO₂ and arranged between the substrate and the chalcopyrite absorbing layer, the additional diffusion of the alkali metal ions from the substrate into the absorbing layer during the manufacturing process is prevented, and the concentration of the alkali metal element within the absorbing layer is adjusted.

That is, in Patent Document 14, an attempt is made to separately supply an alkali metal element (ion), such as Na, of a solar cell comprising a chalcopyrite absorbing layer while controlling the supplied volume, rather than supplying the alkali metal element (ion) from the substrate side. In a case where a glass substrate is used from a cost standpoint, since a high volume of alkali metal ions diffuses from the glass substrate, sometimes resulting in a loss in properties, alkali metal ions are supplied separately and not from the glass substrate for the sake of controllability. Thus, in Patent Document 14, controllability is controlled by the volume of Na supplied. This controllability is the same for substrates other than glass substrates as well; even if the substrate is a conductive substrate such as a metal substrate that does not contain an alkali metal, Na is supplied from an external source similar to the above.

In JP 3503824 B (Patent Document 15), a Na supply layer is provided on a conductive substrate, and Na is supplied to the light absorbing layer through an electrode layer formed thereon.

In JP 2006-165386 A (Patent Document 16) there is disclosed a CIS thin-film solar cell that provides on the glass substrate a non-alkali layer such as silica (SiO₂) that has an alkali barrier function for inhibiting and controlling thermal diffusion of alkali components from the glass substrate to the light absorbing layer when the light absorbing layer is formed.

Additionally, in Applied Physics Letters 93, 124105 (2008) (Non-Patent Document 1), a thin soda-lime glass (SLG) film is formed on both Ti foil and a zirconia (ZrO₂) substrate, and molybdenum (Mo) lower electrodes, so-called back electrodes, are formed thereon. Non-Patent Document 1 discloses a thickness of the thin soda-lime glass film that maximizes efficiency in a case where Ti foil and a zirconia substrate are used.

### SUMMARY OF THE INVENTION

As described above, when a metal plate, etc., other than soda-lime glass (SLG) is used as the solar cell substrate, the problem arises that an alkali metal such as Na must be supplied separately in order to improve the conversion efficiency of the photoelectric conversion layer. For example, even with an anodized aluminum substrate, an Na supply layer needs to be formed in order to diffuse Na at an appropriate concentration into the CIGS photoelectric conversion layer formed on the substrate, improve the CIGS crystal quality, and enhance the conversion efficiency.

Nevertheless, as in the prior art of Patent Documents 1 to 11, when Na is to be diffused into the photoelectric conversion layer and a layer of Na is formed on the back electrodes by vapor deposition, sputtering, or coating, the Na layer formed is altered due to deliquescence, etc., causing the layer to readily delaminate.

Additionally, while a glass layer serving as the insulation layer is formed when a metal substrate is to be used as in Patent Document 12, a great difference in a linear thermal expansion coefficients of the metal substrate and photoelectric conversion layer results in delamination due to the high temperature during film formation, and a small difference in the thermal expansion coefficients of the metal substrate and the photoelectric conversion layer results in failure to achieve adequate withstand voltage since the thickness of the glass layer is intrinsically thin, even though the material may be able to withstand high temperatures. Further, since the glass layer contains an alkali metal ion such as Na, this alkali metal ion diffuses into the photoelectric conversion layer during formation thereof, but has the disadvantage of simultaneously diffusing into the metal substrate as well. As a result, the metal substrate is altered and delamination occurs, making it no longer possible to diffuse the necessary amount of Na into the photoelectric conversion layer.

Further, with the solar cell substrate disclosed in Patent Document 13, the alkali metal ions diffuse into the metal substrate side as well during film formation, causing inadequate supply of the alkali metal ions to the CIGS photoelectric conversion layer and failure to achieve a high photoelectric conversion efficiency; and when the Na ion diffuses into an anodized film serving as the first insulating oxide film, the problem arises that the anodized film becomes altered.

Further, while Patent Document 14 discloses that, when a glass substrate is used as the substrate of a solar cell comprising a chalcopyrite absorbing layer, a diffusion intercepting layer that intercepts additional diffusion of the alkali metal ions from the substrate to within the absorbing layer during manufacturing is disposed between the substrate and the chalcopyrite absorbing layer, the alkali metal requires doping by sputtering, etc., before or during the manufacture of the absorbing layer and the doped alkali metal needs to be precipitated as an alkali metal compound on the back electrodes, i.e., rear electrodes (hereinafter “back electrodes”), in order to supply the alkali metal from the back electrodes during the manufacture of the absorbing layer after the back electrodes are formed. Further, the effect of the diffusion intercepting layer in Patent Document 14 is problematic in that it merely inhibits diffusion of the alkali metal (Na) from the glass substrate, and the disclosed technique of precipitation on the back electrodes is not preferred since it causes delamination and alteration of the back electrodes.

Note, however, that in a case where a conductive substrate that does not contain an alkali metal is used as the substrate, an additional insulation layer is required between the back electrodes and substrate. In such a case, while the substrate does not serve as the alkali metal supply source, thereby eliminating the need to provide a diffusion intercepting layer, the problem arises that the alkali metal must be similarly separately provided. Furthermore, while delamination occurs at high temperatures and a high performance photoelectric conversion element cannot be achieved when a conductive substrate is used and the thermal expansion coefficients of the substrate and photoelectric conversion layer do not match, the conductive substrate disclosed in Patent Document 14 is problematic in that delamination may occur when the thermal expansion coefficients of the conductive substrate and photoelectric conversion layer, or the thermal expansion coefficients of the conductive substrate, photoelectric conversion layer, and an additional insulation layer therebetween deviate from one another.

Further, in the method of Na supply to the photoelectric conversion layer disclosed in Patent Document 15, Na is diffused into the substrate as well, requiring the supply layer to be sufficiently thick in order to ensure that a sufficient amount of Na is diffused into the photoelectric conversion layer side. When the thickness is increased, however, the problem arises that delamination occurs from this supply layer.

Further, the technique of suppressing Na diffusion into the substrate that is disclosed in Patent Document 16, i.e., the blocking effect of the block layer of an oxide film, metal film, or the like, such as SiO₂, which inhibits diffusion of the alkali provided on the glass substrate, is problematic in its inadequacy.

Furthermore, the Ti foil substrate disclosed in Non-Patent Document 1 makes it difficult to maintain insulation properties, resulting in the disadvantage that a solar cell having an integrated structure cannot be formed. Further, with the zirconia substrate disclosed in Non-Patent Document 1, there is the disadvantage that a flexible photoelectric conversion element and solar cell cannot be formed in addition to the disadvantage of high cost.

Further, in general, the interface areas such as that of the insulation layer and back electrode layer or the photoelectric conversion material layer are also problematic in that delamination readily occurs due a difference in thermal expansion coefficients.

In particular, with an anodized aluminum substrate, the diffused Na alters the anodized film, causing an increase in strain after growth of the CIGS photoelectric conversion layer, and delamination of the CIGS photoelectric conversion layer.

Additionally, to decrease the cost of the solar cell and increase productivity, a method of diffusing the alkali metal from the substrate into the photoelectric conversion layer within the short film formation period is required.

It is therefore an object of the present invention to solve the above-described problems of prior art and provide a photoelectric conversion element that is light in weight, flexible, superior in an electrical insulation properties, and capable of sufficiently maintaining and controlling the precision and reproducibility of the amount of alkali metal supplied to the photoelectric conversion layer and increasing photoelectric conversion efficiency; a thin-film solar cell that uses the photoelectric conversion element having the above features; and a manufacturing method of the photoelectric conversion element a photoelectric conversion element that is capable of efficiently manufacturing.

Additionally, it is also an object of the present invention to provide a photoelectric conversion element that exhibits excellent adhesion between the insulation layer and the layer formed thereon and has preferred withstand voltage characteristics and heat resistance; a thin-film solar cell that uses the photoelectric conversion element having the above features; and a manufacturing method of a photoelectric conversion element that is capable of efficiently manufacturing the photoelectric conversion element.

Additionally, it is also an objective of the present invention to provide a photoelectric conversion element and a thin-film solar cell that are capable of being manufactured with improved productivity; and a manufacturing method of a photoelectric conversion element that is capable of manufacturing the photoelectric conversion element with the improved productivity.

To achieve the above object, a first aspect of the present invention provides a photoelectric conversion element comprising: a substrate with an insulation layer made of a metallic substrate and an electrical insulation layer formed on the surface thereof, a diffusion prevention layer made of a nitride and formed on the electrical insulation layer, an alkali supply layer that contains an alkali metal element and is formed on the diffusion prevention layer, a lower electrode formed on the alkali supply layer, a photoelectric conversion layer that is made of a compound semiconductor and is formed on the lower electrode, and an upper electrode that is formed on the photoelectric conversion layer, wherein: the electrical insulation layer is an Al anodized film, and the diffusion prevention layer prevents diffusion of the alkali metal element from the alkali supply layer to the substrate with an insulation layer.

Further, to achieve the above object, a second aspect according to the present invention provides a manufacturing method of a photoelectric conversion element comprising the steps of: forming an Al anodized film serving as an electrical insulation layer on the surface of a metallic substrate to obtain a substrate with in insulation layer, forming a diffusion prevention layer made of a nitride on the electrical insulation layer of the substrate with an insulation layer, forming an alkali supply layer that contains an alkali metal element on the diffusion prevention layer, forming a lower electrode on the alkali supply layer, forming a photoelectric conversion layer made of a compound semiconductor on the lower electrode, and forming an upper electrode on the photoelectric conversion layer, wherein the diffusion prevention layer prevents diffusion of the alkali metal element from the alkali supply layer to the substrate with an insulation layer.

Preferably the metallic substrate is a laminated plate with a metal base and an Al base laminated and integrated, and the process to obtain the substrate with an insulation layer comprises the step of anodizing the Al base to form an anodized film on the surface of the Al base.

In each aspect of the present invention, the compound semiconductor is preferably composed of at least one kind of compound semiconductor of a chalcopyrite structure, more preferably at least one kind of compound semiconductor composed of at least a group Ib element, a group IIIb element, and a group VIb element, and even more preferably the group Ib element is selected from the group consisting of Cu and Ag, the group IIIb element is selected from the group consisting of Al, Ga, and In, and the group VIb element is selected from the group consisting of S, Se, and Te.

Further, the nitride is preferably an electrical insulator, and comprises more preferably at least one kind of TiN, ZrN, BN, and AlN, and most preferably AlN.

Further, the diffusion prevention layer preferably has a thickness of 10 nm to 200 nm, and more preferably 10 nm to 100 nm.

Further, the photoelectric conversion layer is preferably split into a plurality of elements by a plurality of opening grooves, and the plurality of elements is preferably electrically connected in series.

Further, the alkali supply layer is preferably a layer that supplies Na, preferably a silicate glass layer having a content of Na compound, such as Na₂O, of 10% to 30% (7 at. % to 20 at. %), more preferably 15% to 25% (10 at % to 16 at. %), and preferably a layer formed by sputtering. Further, the thickness of the alkali supply layer is preferably 100 nm to 800 nm, and more preferably 100 nm to 400 nm.

Further, the lower electrode is made of Mo, and the thickness thereof is preferably 200 nm to 600 nm, and more preferably 200 nm to 400 nm.

Further, the metallic substrate is preferably a laminated plate with a metal base and Al base laminated and integrated, and more preferably a laminated plate with the metal base and the Al base integrated by compression bonding.

Further, the metal base is preferably a steel material, an alloy steel material, a Ti foil, or a dual-layer base made of a Ti foil and a steel material; the alloy steel material is preferably made of carbon steel and a ferrite stainless steel; and the thermal expansion coefficient difference between the metal base and the photoelectric conversion layer is preferably less than 3×10⁻⁶/° C., and more preferably less than 1×10⁻⁶/° C.

Further, the metallic substrate comprises a laminated plate wherein carbon steel or an alloy steel material made of a ferrite stainless steel is integrated with an Al base by compression bonding, the lower electrode is made of Mo, and the photoelectric conversion layer is a layer comprising as its main component at least one kind of compound semiconductor composed of a group Ib element, a group IIIb element, and a group VIb element.

Further, the anodized film preferably has a porous structure.

Additionally, to achieve the above object, a third aspect of the present invention is to provide a thin-film solar cell comprising the photoelectric conversion element of the first aspect of the present invention.

According to the present invention, it is possible to increase the amount of alkali metal element ions or alkali earth metal element ions (hereinafter represented by “alkali metal”) diffused from the alkali supply layer to the photoelectric conversion layer and, as a result, improve the amount of supply thereof, enhance the photoelectric conversion efficiency of the photoelectric conversion layer, achieve a photoelectric conversion layer having a more favorable conversion efficiency, and realize a photoelectric conversion element that has a high photoelectric conversion efficiency.

Further, according to the present invention, it is possible to achieve a photoelectric conversion layer that has a favorable conversion efficiency, even when the alkali supply layer is thin. In particular, in a case where the alkali supply layer is soda-lime glass (SLG), decreasing the thickness of the layer makes it possible to prevent the alkali supply layer from becoming the origin of delamination, shorten the alkali supply layer formation time, and improve productivity.

Further, according to the present invention, it is possible to favorably and appropriately control the amount of alkali metal, such as Na, diffused from the alkali supply layer to the photoelectric conversion layer by the film thickness of the alkali supply layer.

Further, according to the present invention, it is possible to prevent diffusion of the alkali metal from the alkali supply layer to the metallic substrate, thereby preventing alterations caused by diffusion of the alkali metal, such as Na, into the anodized film and, as a result, preventing delamination of the metallic substrate and photoelectric conversion layer.

Further, according to the present invention, it is possible to make the linear thermal expansion coefficients of the diffusion prevention layer, metallic substrate, and photoelectric conversion layer uniform and thus maintain and improve the adhesion between the diffusion prevention film, metallic substrate, and photoelectric conversion layer, thereby preventing delamination of the metallic substrate and photoelectric conversion layer.

Furthermore, according to the present invention, in addition to the insulation layer of the substrate with an insulation layer, the diffusion prevention layer comprises an insulator made of a nitride, thereby making it possible to further improve the insulation (withstand voltage) properties and heat resistance of the substrate with an insulation layer and achieve a photoelectric conversion element and solar cell having high withstand voltage characteristics.

Further, according to the present invention, it is possible to use a metallic substrate that has a flexible insulation layer and comprises an aluminum (Al) base containing Al as its main component, making it possible to achieve a substrate having characteristics that result in minimal distortion and zero cracking even at high temperatures. Therefore, according to the present invention, it is possible to make it possible to achieve a photoelectric conversion element that is light in weight, flexible, superior in an electrical insulation properties, and capable of increasing photoelectric conversion efficiency.

### BRIEF DESCRIPTION OF THE DRAWINGS

FIG. 1 is a schematic cross-sectional view illustrating a thin-film solar cell constituting a thin-film solar cell comprising a photoelectric conversion element according to an embodiment of the present invention.

FIG. 2A is a schematic cross-sectional view illustrating a substrate used in a thin-film solar cell comprising a photoelectric conversion element according to an embodiment of the present invention, and FIG. 2B is a schematic cross-sectional view illustrating another example of a substrate used in a thin-film solar cell comprising a photoelectric conversion element according to an embodiment of the present invention.

FIG. 3 is a graph showing the relationship between conversion efficiency and the thickness of the alkali supply layer.

### DETAILED DESCRIPTION OF THE INVENTION

The photoelectric conversion element, thin-film solar cell, and photoelectric conversion element manufacturing method of the present invention will now be described based on preferred embodiments illustrated in the accompanying drawings.

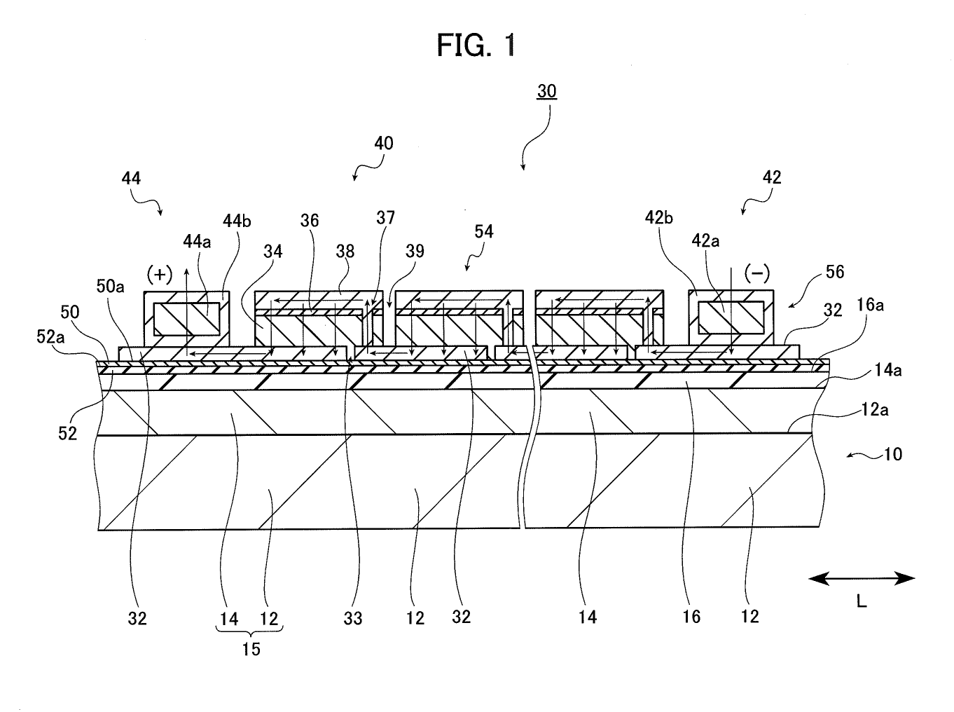

FIG. 1 is a schematic cross-sectional view illustrating a thin-film solar cell constituting a thin-film solar cell comprising a photoelectric conversion element according to an embodiment of the present invention.

A thin-film solar cell 30 of the embodiment shown in FIG. 1 is used in a solar cell module or a solar cell sub-module constituting this solar cell module. The thin-film solar cell 30 comprises, for example, a substrate 10 with an insulation layer (hereinafter “substrate 10”) comprising a grounded metallic substrate 15 of a substantially rectangular shape and an electrical insulation layer 16 formed on the metallic substrate 15, a diffusion prevention layer 52 formed on the insulation layer 16, an alkali supply layer 50 formed on the diffusion prevention layer 52, a plurality of power generating cells (solar cells) 54 connected in series and formed on the alkali supply layer 50, and a power generating layer 56 comprising a first conductive member 42 connected to one and a second conductive member 44 connected to another of the plurality of power generating cells 54. Note that the body comprising one of the power generating cells 54, the corresponding substrate 10, the diffusion prevention layer 52, and the alkali supply layer 50 is herein called a photoelectric conversion element 40, but the thin-film solar cell 30 itself shown in FIG. 1 may be called a photoelectric conversion element.

First, the substrate used in the thin-film solar cell comprising a photoelectric conversion element according to an embodiment of the present invention will be described.

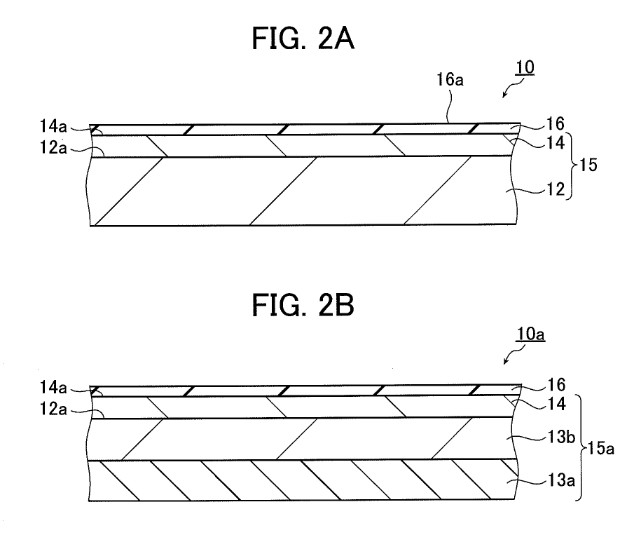

FIG. 2A is a schematic cross-sectional view illustrating a substrate used in a thin-film solar cell comprising a photoelectric conversion element according to an embodiment of the present invention, and FIG. 2B is a schematic cross-sectional view illustrating another example of a substrate used in a thin-film solar cell comprising a photoelectric conversion element according to an embodiment of the present invention.

As shown in FIG. 2A, the substrate 10 is a substrate with an insulation layer comprising the metallic substrate 15 formed of a metal base 12 and an aluminum base 14 (hereinafter “Al base 14”) that has aluminum as its main component, and the insulation layer 16.

In the substrate 10, the Al base 14 is formed on a surface 12a of the metal base 12 to constitute the metallic substrate 15, and the insulation layer 16 is formed on a surface 14a of the Al base 14 of the metallic substrate 15. Further, the metallic substrate 15 is a substrate wherein the metal base 12 and the Al base 14 are layered and unified, i.e., an Al clad base or an Al clad substrate.

The substrate 10 of the embodiment is used as a substrate of a photoelectric conversion element and thin-film solar cell, and is flat in shape, for example. The shape and size of the substrate 10 are suitably determined in accordance with the size, etc., of the photoelectric conversion element and thin-film solar cell in which it is applied. When used in a thin-film solar cell, the substrate 10 is square or rectangular in shape, with the length of one side exceeding 1 m, for example.

In the substrate 10, the material used for the metal base 12 is a flat-shaped or foil-shaped metal material, examples including a steel material such as a carbon steel or ferrite stainless steel.

A steel material used for the metal base 12 exhibits greater strength in temperatures of 300° C. and higher than aluminum alloy, achieving a predetermined heat resistance in the substrate 10.

The carbon steel used for the metal base 12 is a carbon steel for mechanical structures having a carbon content of 0.6 mass % or less, for example. Examples of materials used as the carbon steel for a mechanical structure include materials generally referred to as SC materials.

Further, the materials that can be used as the ferrite stainless steel include SUS430, SUS405, SUS410, SUS436, and SUS444.

Examples of materials that can be used as the steel material in addition to the above include materials generally referred to as SPCC materials (cold-rolled carbon steel sheets).

Note that, other than the above, the metal base 12 may be made of a kovar alloy, titan, or a titan alloy. The material used as titan is pure titan, and the materials used as the titan alloy is Ti-6Al-4V and Ti-15V-3Cr-3Al-3Sn, which are wrought alloys. These metals also are used in a flat shape or foil shape.

The metal base 12 is preferably a metal or alloy that has a linear thermal expansion coefficient that is lower than aluminum and aluminum alloy, exhibits high rigidity, and achieves high heat resistance.

The thickness of the metal base 12 affects flexibility, and is thus preferably thin, within a range not associated with an excessive lack of rigidity.

In the substrate 10 of this embodiment, the thickness of the metal base 12 is, for example, 10 μm to 800 μm, and preferably 30 μm to 300 μm. More preferably, the thickness is 50 μm to 150 μm. The reduced thickness of the metal base 12 is also preferred from a raw material cost standpoint.

The metal base 12 is a material that has flexibility. That is, for flexibility, the metal base 12 employed is preferably ferrite stainless steel.

The Al base 14 comprises aluminum (Al) as its main component, meaning that the aluminum content is at least 90 mass %.

Examples of materials used as the Al base 14 include aluminum and aluminum alloy. The aluminum or aluminum alloy used for the Al base 14 preferably does not contain any unnecessary intermetallic compounds. Specifically, aluminum with minimal foreign matter having a purity of at least 99 mass % is preferred. For example, 99.99 mass % Al, 99.96 mass % Al, 99.9 mass % Al, 99.85 mass % Al, 99.7 mass % Al, and 99.5 mass % Al are preferred. Further, the aluminum alloy used may be an alloy with added elements that do not readily form intermetallic compounds. Examples include an aluminum alloy formed by adding magnesium to 99.9 mass % Al in an amount of 2.0 mass % to 7.0 mass %. Elements other than magnesium that may be added include those having a high solubility limit, such as Cu and Si.

Increasing the purity of the aluminum of the Al base 14 makes it possible to avoid occurring intermetallic compounds, which cause deposits, and increase the integrity of the insulation layer 16. In a case where an aluminum alloy is anodized, the possibility exists that intermetallic compounds will become the origin of poor insulation; and this possibility increases as the amount of intermetallic compounds increases.

The thickness of the Al base 14 is, for example, 5 μm to 150 μm, and preferably 10 μm to 100 μm. More preferably, the thickness is 20 μm to 50 μm.

The Al base 14 has a surface roughness in terms of, for example, an arithmetic mean roughness Ra, of up to 1 μm. This surface roughness is preferably up to 0.5 μm and more preferably up to 0.1 μm.

Note that the surface of the Al base 14 may have a mirror finish. This mirror finish is formed using, for example, the method described in JP 4212641 B, JP 2003-341696 A, JP 7-331379 A, JP 2007-196250 A, or JP 2000-223205 A.

In the substrate 10, the insulation layer 16 is for insulation and preventing damage from mechanical impact during handling. This insulation layer 16 is made of an anodized film [aluminum anodized film (aluminum film)].

The insulation layer 16 preferably has a thickness of at least 5 μm and more preferably at least 10 μm. An excessively large thickness of the insulation layer 16 reduces its flexibility and increases the cost and time required for formation thereof, and is thus not preferred. In practice, the thickness of the insulation layer 16 is up to 50 μm and preferably up to 30 μm. Therefore, the preferred thickness of the insulation layer 16 is from 0.5 μm to 50 μm.

A surface 18a of the insulation layer 16 has a surface roughness in terms of, for example, the arithmetic mean roughness Ra, of up to 1 μm, preferably up to 0.5 μm, and more preferably up to 0.1 μm.

The strength of the base material 10 requires a tensile strength of at least 5 MPa during heat treatment at 500° C. or higher, and is therefore preferably at least 10 MPa.

Further, to ensure that creep deformation does not occur during heat treatment at 500° C. or higher, the strength that allows up to 0.1% plastic deformation when the material is maintained for 10 minutes at 500° C. is preferably at least 0.2 MPa, more preferably at least 0.4 MPa, and even more preferably at least 1 MPa.

The substrate 10 includes the metal base 12, the Al base 14, and the insulation layer 16 which are all made of flexible materials, and is therefore flexible as a whole. An alkali supply layer, a diffusion prevention layer, a back electrodes serving as the lower electrodes, the photoelectric conversion layer, and the transparent electrodes serving as the upper electrodes can be thus formed on the insulation layer 16 side of the substrate 10 by, for example, a roll-to-roll process.

Further, while the substrate 10 of the embodiment comprises a metallic substrate 15 having a dual-layer structure of the metal base 12 and the Al base 14, the present invention permits at least one layer of metal base 12, and is not limited to one layer, allowing a plurality of layers.

As in a substrate 10a shown in FIG. 2B, the metal base may have a dual-layer structure comprising a first metal base 13a and a second metal base 13b, for example.

In such a case, the first metal base 13a is made of titan or a titan alloy, for example, and the second metal base 13b is made of a steel material similar to the metal base 12. Note that the second metal base 13b may be made of titan or a titan alloy, and the first metal base 13a may be made of a steel material similar to the metal base 12.

Next, the manufacturing method of the substrate 10 of the embodiment will be described.

First, the metal base 12 is prepared. This metal base 12 is formed to a predetermined shape and size suitable to the size of the substrate 10 to be formed.

Then, the Al base 14 is formed on the surface 12a of the metal base 12. The metallic substrate 15 is thus formed.

The method of forming the Al base 14 on the surface 12a of the metal base 12 is not particularly limited as long as integral connection between the metal base 12 and the Al base 14 that can ensure the adhesion therebetween is achieved. The formation method of the Al base 14 used includes, for example, a vapor deposition method, vapor phase method such as sputtering, plating method, and pressurizing and bonding after surface cleaning. Pressure-bonding by rolling is preferably used to form the Al base 14 in terms of the cost and mass production capability.

Note that both the surface 12a and the back surface of the metal base 12 may form the Al base 14, as described above.

Next, the insulation layer 16 is formed on the surface 14a of the Al base 14 of the metallic substrate 15. The substrate 10 is thus obtained. The method of forming the anodized film serving as the insulation layer 16 is described below.

The anodized film serving as the insulation layer 16 can be formed by immersing the metal base 12 serving as the anode in an electrolytic solution together with the cathode and applying voltage between the anode and the cathode. In the case, the metal base 12 forms a local cell with the Al base 14 upon contact with the electrolytic solution and therefore the metal base 12 contacting the electrolytic solution is to be masked and isolated using a masking film (not shown). That is, the end surface and the back surface 12b of the metal base 12 other than the surface 14a of the Al base 14 need to be isolated using a masking film (not shown).

Where necessary, pre-anodization may include steps of subjecting the surface of the Al base 14 to cleaning and polishing/smoothing processes.

Carbon or aluminum is used for the cathode during anodization. The electrolyte used is an acidic electrolytic solution containing one or more than one acid selected from the group consisting of sulfuric acid, phosphoric acid, chromic acid, oxalic acid, malonic acid, sulfamic acid, benzenesulfonic acid, and amidosulfonic acid. The anodizing conditions vary with the type of electrolyte used and are not particularly limited. By way of example, appropriate anodizing conditions are an electrolyte concentration of 1% to 80%, a solution temperature of 5° C. to 70° C., a current density of 0.005 A/cm² to 0.60 A/cm², a voltage of 1 V to 200 V, and an electrolysis time of 3 minutes to 500 minutes. The electrolytic solution preferably contains a sulfuric acid, phosphoric acid, or oxalic acid, or mixture thereof. Electrolytes as described above are used preferably with an electrolyte concentration of 4 mass % to 30 mass %, a solution temperature of 10° C. to 30° C., a current density of 0.002 A/cm² to 0.30 A/cm², and a voltage of 20 V to 100 V.

During the anodization treatment, an oxidation reaction proceeds substantially in the vertical direction from the surface 14a of the Al base 14 to form the anodized film on the surface 14a of the Al base 14. In cases where any of the above electrolytic solutions is used, the anodized film is of a porous type in which a large number of fine columns in the shape of a substantially regular hexagon as seen from above are arranged without gaps, and a micropore having a rounded bottom is formed at the core of each fine column, the bottom of each fine column having a barrier layer with a thickness of typically 0.02 μm to 0.1 μm.

The anodized film having such a porous structure has a low Young's modulus compared to a single aluminum oxide film of a non-porous structure, and high crack resistance due to its flexural capacity and thermal expansion difference at high temperatures.

Note that, not an anodized film having porous fine columns arranged therein but a dense anodized film (non-porous aluminum oxide single film) is obtained by electrolytic treatment in a neutral electrolytic solution such as boric acid without using the acidic electrolytic solution. After the porous anodized film is formed in the acidic electrolytic solution, an anodized film that increases the thickness of the barrier layer may be formed by a pore filling method that subjects the film to electrolytic treatment once again in a neutral electrolytic solution. The film can have higher insulation properties by increasing the thickness of the barrier layer.

The electrolytic solution used in anodization treatment is preferably a sulfuric acid aqueous solution or oxalic acid solution. The integrity of the anodized film originates from its superior oxalic acid solution and the ongoing treatment productivity of the anodized film originates from its superior sulfuric acid aqueous solution.

As described above, the anodized film serving as the insulation layer 16 preferably has a thickness of 0.5 μm to 50 μm. This thickness can be controlled by the magnitudes of the current and voltage in constant current electrolysis and constant voltage electrolysis, and the electrolysis time.

In cases where it is desired to increase the insulation properties of the insulation layer 16 formed by anodization, pore sealing treatment can be performed using, for example, a boric acid solution. The pore sealing treatment is a treatment for sealing and/or filling pores and/or voids.

The anodization treatment can be performed using, for example, a known anodizing device of a so-called roll-to-roll process.

Next, after the anodizing treatment, the masking film (not shown) is peeled off. The substrate 10 can be thus formed.

The substrate 10 of the present invention may employ the metallic substrate 15 comprising the Al base 14 having aluminum (Al) as its main component and a flexible anodic oxide coating serving as the insulation layer 16, thereby providing the superior characteristics of minimal distortion and zero cracking at high temperatures.

Next, the photoelectric conversion element 40 of the thin-film solar cell 30 of the embodiment shown in FIG. 1 will be described.

In the thin-film solar cell 30 (thin-film solar cell sub-module, for example) of the embodiment, the diffusion prevention layer 52 is formed on a surface of the aforementioned substrate 10, that is, a surface 16a of the insulation layer 16, and the conductive alkali supply layer 50 is formed on a surface 52a of this diffusion prevention layer 52.

The solar cell 30 includes a plurality of the photoelectric conversion elements 40, the first conductive member 42, and the second conductive member 44.

The photoelectric conversion element 40 makes up the thin-film solar cell 30 and comprises the substrate 10, the diffusion prevention layer 52, the alkali supply layer 50, and the power generating cell (solar cell) 54 comprising a back electrodes 32, a photoelectric conversion layers 34, a buffer layers 36, and a transparent electrode 38.

As described above, the diffusion prevention layer 52 is formed on the surface 16a of the insulation layer 16, and the alkali supply layer 50 is formed on this diffusion prevention layer 52. The back electrodes 32 of the power generating cell 54, the photoelectric conversion layers 34, the buffer layers 36, and the transparent electrodes 38 are layered in that order on a surface 50a of the alkali supply layer 50.

The back electrodes 32 are formed on the surface 50a of the flexible alkali supply layer 50 so as to share a separation groove (P1) 33 with adjacent back electrodes 32. The photoelectric conversion layers 34 are formed on the back electrodes 32 so as to fill the separation grooves (P1) 33. The buffer layers 36 are formed on the surfaces of the photoelectric conversion layers 34. The photoelectric conversion layers 34 and the buffer layers 36 are separated from an adjacent photoelectric conversion layer 34 and an adjacent buffer layer 36 by grooves (P2) 37 reaching the back electrodes 32. The grooves (P2) 37 are formed in positions different from those of the separation grooves (P1) 33 separating the back electrodes 32.

The transparent electrodes 38 are formed on the surfaces of the buffer layers 36 so as to fill the grooves (P2) 37.

Opening grooves (P3) 39 are formed so as to reach the back electrodes 32 through the transparent electrodes 38, the buffer layers 36, and the photoelectric conversion layers 34. In the thin-film solar cell 30, the respective photoelectric conversion elements 40 are electrically connected in series in a longitudinal direction L of the substrate 10 through the back electrodes 32 and the transparent electrodes 38.

The photoelectric conversion elements 40 of this embodiment are so-called integrated type photoelectric conversion elements (solar cells) and have a configuration such, for example, that the back electrodes 32 are molybdenum electrodes, the photoelectric conversion layers 34 are formed of a semiconducting compound having a photoelectric conversion function such as a CIGS layer, the buffer layers 36 are formed of CdS, and the transparent electrodes 38 are formed of ZnO.

The photoelectric conversion elements 40 are formed so as to extend in the width direction perpendicular to the longitudinal direction L of the substrate 10. Therefore, the back electrodes 32 also extend in the width direction of the substrate 10.

As illustrated in FIG. 1, the first conductive member 42 is connected to a rightmost back electrode 32. The first conductive member 42 is provided to collect the output from the negative electrode as will be described onto the outside. Although a photoelectric conversion element 40 is formed on the rightmost back electrode 32, that photoelectric conversion element 40 is removed by, say, a laser scribing or mechanical scribing technique to expose the back electrode 32.

The first conductive member 42 is, for example, a member in the shape of an elongated strip which extends substantially linearly in the width direction of the substrate 10 and is connected to the rightmost back electrode 32. As shown in FIG. 1, the first conductive member 42 has, for example, a copper ribbon 42a covered with a coating material 42b made of an alloy of indium and copper. The first conductive member 42 is connected to the back electrode 32 by, for example, ultrasonic soldering.

The second conductive member 44 is provided to collect the output from the positive electrode as will be described onto the outside. Like the first conductive member 42, the second conductive member 44 is a long strip connected to a leftmost back electrode 32 and extending in a substantially linear shape in the width direction of the substrate 10. Although a photoelectric conversion element 40 is formed on the leftmost back electrode 32, that photoelectric conversion element 40 is removed by, say, a laser scribing or mechanical scribing technique to expose the back electrode 32.

The second conductive member 44 is composed similarly to the first conductive member 42 and has, for example, a copper ribbon 44a covered with a coating material 44b made of an alloy of indium and copper.

The first conductive member 42 and the second conductive member 44 may be formed of a tin-coated copper ribbon. Further, the first conductive member 42 and the second conductive member 44 may be secured by such means as, for example, a conductive adhesive and conductive tape in lieu of by an ultrasonic solder.

The photoelectric conversion layer 34 in the photoelectric conversion elements 40 of the embodiment under consideration is made of, for example, CIGS and can be manufactured by a known method of manufacturing CIGS solar cells.

The separation grooves (P1) 33 of the back electrodes 32, the grooves (P2) 37 reaching the back electrodes 32, and the opening grooves (P3) 39 reaching the back electrodes 32 may be formed by laser scribing or mechanical scribing.

In the solar cell 30, light entering the photoelectric conversion elements 40 from the side bearing the transparent electrodes 38 passes through the transparent electrodes 38 and the buffer layers 36 and causes the photoelectric conversion layers 34 to generate electromotive force, thus producing a current that flows, for example, from the transparent electrodes 38 to the back electrodes 32. Note that the arrows shown in FIG. 1 indicate the directions of the current, and the direction in which electrons move is opposite to that of current. Therefore in the photoelectric conversion unit 48, the leftmost back electrode 32 in FIG. 1 has a positive polarity (plus polarity) and the rightmost back electrode 32 has a negative polarity (minus polarity).

In this embodiment, electric power generated in the solar cell 30 can be output from the solar cell 30 through the first conductive member 42 and the second conductive member 44.

Also in this embodiment, the first conductive member 42 has a negative polarity, and the second conductive member 44 has a positive polarity. The polarities of the first conductive member 42 and the second conductive member 44 may be reversed; their polarities may vary according to the configuration of the photoelectric conversion elements 40, the configuration of the solar cell 30, and the like.

In this embodiment, the respective photoelectric conversion elements 40 formed are connected in series in the longitudinal direction L of the substrate 10 through the back electrodes 32 and the transparent electrodes 38, but this is not the sole case of the invention. For example, the respective photoelectric conversion elements 40 may be formed so as to be connected in series in the width direction through the back electrodes 32 and the transparent electrodes 38.

The back electrodes 32 and the transparent electrodes 38 of the photoelectric conversion elements 40 are both provided to collect current generated by the photoelectric conversion layers 34. Both the back electrodes 32 and the transparent electrodes 38 are each made of a conductive material. The transparent electrodes 38, provided on the side from which light is admitted, need to be pervious to light.

The back electrodes 32 are formed, for example, of Mo, Cr or W, or a material composed of two or more of these. The back electrodes 32 may have a single-layer structure or a laminated structure such as a dual-layer structure. The back electrodes 32 are preferably made of molybdenum.

The back electrodes 32 may be formed by any of vapor-phase film deposition methods as appropriate such as electron-beam deposition and sputtering.

The back electrodes 32 generally have a thickness of about 800 nm, preferably 200 nm to 600 nm, and more preferably 200 nm to 400 nm. By making the thickness of the back electrodes 32 thinner than standard, it is possible to increase the diffusion speed of the alkali metal from the alkali supply layer 50 to the photoelectric conversion layers 34, as will be described later. Moreover, with this arrangement, the material costs of the back electrodes 32 can be reduced, and the formation speed of the back electrodes 32 can be increased.

The transparent electrodes 38 are formed, for example, of ZnO added with Al, B, Ga, Sb, etc., ITO (indium tin oxide), SnO₂, or a material composed of two or more of these. The transparent electrodes 38 may have a single-layer structure or a laminated structure such as a dual-layer structure. The thickness of the transparent electrodes 38, which is not specifically limited, is preferably 0.3 μm to 1 μm.

The method of forming the transparent electrodes 38 is not particularly limited, and the transparent electrodes 38 may be formed by vapor-phase deposition techniques such as electron beam evaporation and sputtering or a coating method.

The buffer layers 36 are provided to protect the photoelectric conversion layers 34 when forming the transparent electrodes 38 and allow the light passing through the transparent electrodes 38 to enter the photoelectric conversion layers 34.

The buffer layer 36 is made of, for example, CdS, ZnS, ZnO, ZnMgO, or ZnS (O, OH) or a combination thereof.

The buffer layers 36 preferably have a thickness of 30 nm to 100 nm. The buffer layer 36 is formed by, for example, chemical bath deposition (CBD) method.

The photoelectric conversion layers 34 absorb light having reached through the transparent electrodes 38 and the buffer layers 36 to generate current and have a photoelectric conversion function. According to the embodiment under consideration, the photoelectric conversion layers 34 are not particularly limited in structure; the photoelectric conversion layers 34 are made of, for example, at least one compound semiconductor of a chalcopyrite structure. The photoelectric conversion layers 34 may be formed of at least one kind of compound semiconductor composed of a group Ib element, a group IIIb element, and a group VIb element.

For a high optical absorptance and a high photoelectric conversion efficiency, the photoelectric conversion layers 34 are preferably formed of at least one kind of compound semiconductor composed of at least one kind of group Ib element selected from the group consisting of Cu and Ag, at least one kind of group IIIb element selected from the group consisting of Al, Ga, and In, and at least one kind of group VIb element selected from the group consisting of S, Se, and Te. Examples of this compound semiconductor include CuAlS₂, CuGaS₂, CuInS₂, CuAlSe₂, CuGaSe₂, CuInSe₂(CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ) Se₂(CIGS), Cu(In₁₋ₓAlₓ)Se₂, Cu(In₁₋ₓGaₓ)(S,Se)₂, Ag(In₁₋ₓGaₓ)Se₂, and Ag(In₁₋ₓGaₓ)(S,Se)₂.

The photoelectric conversion layers 34 preferably contain CuInSe₂(CIS) and/or Cu(In,Ga)Se₂(CIGS), which is obtained by dissolving Ga in the former. CIS and CIGS are semiconductors each having a chalcopyrite crystal structure and reportedly have a high optical absorptance and a high photoelectric conversion efficiency. Further, CIS and CIGS have less deterioration of the efficiency under exposure to light and exhibit excellent durability.

The photoelectric conversion layers 34 contain impurities for obtaining a desired semiconductor conductivity type.

Impurities may be added to the photoelectric conversion layers 34 by diffusion from adjacent layers and/or direct doping into the photoelectric conversion layers 34. The photoelectric conversion layers 34 permit presence therein of a component element of group I-III-VI semiconductors and/or a density distribution of impurities; the photoelectric conversion layers 34 may contain a plurality of layer regions formed of materials having different semiconductor properties such as n-type, p-type, and i-type.

For example, a CIGS semiconductor, when given a thickness-wise distribution of Ga amount in the photoelectric conversion layers 34, permits control of band gap width, carrier mobility, etc. and thus achieves a high photoelectric conversion efficiency.

The photoelectric conversion layers 34 may contain one or two or more kinds of semiconductors other than group I-III-VI semiconductors. Such semiconductors other than group I-III-VI semiconductors include a semiconductor formed of a group IVb element such as Si (group IV semiconductor), a semiconductor formed of a group IIIb element and a group Vb element (group III-V semiconductor) such as GaAs, and a semiconductor formed of a group IIb element and a group VIb element (group II-VI semiconductor) such as CdTe. The photoelectric conversion layers 34 may contain any component other than a semiconductor and impurities used to obtain a desired conductivity type, provided that no detrimental effects are thereby produced on the properties.

The photoelectric conversion layers 34 may contain a group I-III-VI semiconductor in any amount as deemed appropriate. The ratio of a group I-III-VI semiconductor contained in the photoelectric conversion layers 34 is preferably 75 mass % or more and, more preferably, 95 mass % or more and, most preferably, 99 mass % or more.

Note that when the photoelectric conversion layers 34 in the embodiment are made of compound semiconductors formed of a group Ib element, a group IIIb element, and a group VIb element, the metal base 12 is preferably made of carbon steel or ferrite stainless steel, and the back electrodes 32 are preferably made of molybdenum.

Exemplary known methods of forming the CIGS layer include 1) simultaneous multi-source evaporation, 2) selenization, 3) sputtering, 4) hybrid sputtering, and 5) mechanochemical processing.

1) Known simultaneous multi-source evaporation methods include:

a three-stage method (J. R. Tuttle et al., Mat. Res. Soc. Symp. Proc., Vol. 426 (1966), p. 143, etc.) and a simultaneous evaporation method by EC group (L. Stolt et al.: Proc. 13th ECPVSEC (1995, Nice), 1451, etc.).

According to the first-mentioned three-phase method, firstly, In, Ga, and Se are simultaneously evaporated under high vacuum at a substrate temperature of 300° C., which is then increased to 500° C. to 560° C. to simultaneously vapor-deposit Cu and Se, whereupon In, Ga, and Se are simultaneously evaporated. The latter simultaneous evaporation method by EC group is a method which involves evaporating Cu excess CIGS in an earlier stage of evaporation, and evaporating In excess CIGS in the latter half of the stage.

Improvements have been made on the foregoing methods to improve the crystallinity of CIGS films, and the following methods are known:

a) Method using ionized Ga (H. Miyazaki et al., Phys. Stat. Sol. (a), Vol. 203 (2006), p. 2603, etc.);
b) Method using cracked Se (a pre-printed collection of speeches given at the 68th Academic Lecture by the Japan Society of Applied Physics) (autumn, 2007, Hokkaido Institute of Technology), 7P-L-6, etc.);
c) Method using radicalized Se (a pre-printed collection of speeches given at the 54th Academic Lecture by the Japan Society of Applied Physics) (spring, 2007, Aoyama Gakuin Univ.), 29P-ZW-10, etc.); and
d) Method using a light excitation process (a pre-printed collection of speeches given at the 54th Academic Lecture by the Japan Society of Applied Physics) (spring, 2007, Aoyama Gakuin Univ.), 29P-ZW-14, etc.).

2) The selenization method is also called a two-stage method, whereby firstly a metal precursor formed of a laminated film such as a Cu layer/In layer, a (Cu—Ga) layer/In layer, or the like is formed by sputter deposition, vapor deposition, or electrodeposition, and the film thus formed is heated in selenium vapor or hydrogen selenide to a temperature of 450° C. to 550° C. to produce a selenide such as Cu(In₁₋ₓGaₓ)Se₂ by thermal diffusion reaction. This method is called vapor-phase selenization. Another exemplary method is solid-phase selenization in which solid-phase selenium is deposited on a metal precursor film and selenized by a solid-phase diffusion reaction using the solid-phase selenium as the selenium source.

In order to avoid abrupt volume expansion that may take place during the selenization, selenization is implemented by known methods including a method in which selenium is previously mixed into the metal precursor film at a given ratio (T. Nakada et al., Solar Energy Materials and Solar Cells 35 (1994), 204-214, etc.); and a method in which selenium is sandwiched between thin metal films (e.g., as in Cu layer/In layer/Se layer . . . Cu layer/In layer/Se layer) to form a multi-layer precursor film (T. Nakada et al., Proc. of 10th European Photovoltaic Solar Energy Conference (1991), 887-890, etc.).

An exemplary method of forming a graded band gap CIGS film is a method which involves first depositing a Cu—Ga alloy film, depositing an In film thereon and selenizing with a Ga concentration gradient in the film thickness direction making use of natural thermal diffusion (K. Kushiya et al., Tech. Digest 9th Photovoltaic Science and Engineering Conf. Miyazaki, 1996 (Intn. PVSEC-9, Tokyo, (1996), p. 149, etc.).

3) Known sputter deposition techniques include: one using CuInSe₂ polycrystal as a target, one called two-source sputter deposition using Cu₂Se and In₂Se₃ as a target and H₂Se/Ar mixed gas as sputter gas (J. H. Ermer, et al., Proc. 18th IEEE Photovoltaic Specialists Conf. (1985), 1655-1658, etc.), and one called three-source sputter deposition whereby a Cu target, an In target, and an Se or CuSe target are sputtered in Ar gas (T. Nakada, et al., Jpn. J. Appl. Phys. 32 (1993), L1169-L1172, etc.).

4) Exemplary known methods for hybrid sputtering include one in which Cu and In metals are subjected to DC sputtering, while only Se is vapor-deposited in the aforementioned sputter deposition method (T. Nakada, et al., Jpn. Appl. Phys. 34 (1995), 4715-4721, etc.).

5) An exemplary method for mechanochemical processing includes a method in which a material selected according to the CIGS composition is placed in a planetary ball mill container and mixed by mechanical energy to obtain pulverized CIGS, which is then applied to a substrate by screen printing and annealed to obtain a CIGS film (T. Wada et al., Phys. Stat. Sol. (a), Vol. 203 (2006), p. 2593, etc.).

Other exemplary methods for forming a CIGS film include screen printing, close-spaced sublimation, MOCVD, and spraying (wet deposition). For example, crystals with a desired composition can be obtained by a method which involves forming a fine particle film containing a group Ib element, a group IIIb element and a group VIb element on a substrate by, for example, screen printing (wet deposition) or spraying (wet deposition) and subjecting the fine particle film to pyrolysis treatment (which may be a pyrolysis treatment carried out under a group VIb element atmosphere) (JP 9-74065 A, JP 9-74213 A, etc.).

In this embodiment, the difference between the coefficients of linear thermal expansion of the metal base 12 and the photoelectric conversion layer 34 is preferably less than 3×10⁻⁶/° C.

The coefficient of linear thermal expansion of the main compound semiconductors serving as the photoelectric conversion layer 34 is, for example, 10×10⁻⁶/° C. for Cu(InGa)Se₂, which is representative of the group I-III-VI.

A large thermal expansion difference between the metal base 12 and the photoelectric conversion layer 34 may cause a film deposition defect such as delamination upon cooling of the compound semiconductor deposited on the substrate 10 at a high temperature of at least 500° C. for the photoelectric conversion layer 34. A large internal stress within the compound semiconductor due to the difference in the thermal expansion from the metal base 12 may lower the photoelectric conversion efficiency of the photoelectric conversion layer 34. A difference in the coefficient of linear expansion between the metal base 12 and the photoelectric conversion layer 34 (compound semiconductor) of less than 3×10⁻⁶/° C. does not readily cause delamination or other film deposition defects, and is therefore preferred. More preferably, the difference in the coefficient of linear expansion is less than 1×10⁻⁶/° C. The thermal expansion coefficient and the difference in the thermal expansion coefficient are obtained at room temperature (23° C.).

The alkali supply layer 50 diffuses the alkali metal element (ion) or alkali-earth metal element (ion), such as Na(Na⁺) for example, into the photoelectric conversion layers 34 (CIGS layers), thereby supplying alkali metal or alkali-earth metal, for example, during formation of the photoelectric conversion layers 34. The alkali supply layer 50 is made of an insulating material or an electrical conductive material, for example. The insulating material used is not particularly limited and will be described in detail later. An exemplary insulating material includes a silicate glass, such as soda-lime glass (SLG) having Na₂O, K₂O, CaO, MgO, Al₂O₃, B₂O₃, and SiO₂ as its main components, for example. On the other hand, the conductive material used is not particularly limited as well and will be described in detail later. An exemplary conductive material includes a metal such as Mo that contains an alkali metal such as Na, for example.

The alkali supply layer 50 may have a single-layer structure, or may have a multiple-layer structure in which layers of different compositions are laminated.

When a silicate glass layer of soda-lime glass (SLG), for example, is used, the alkali supply layer 50 preferably has within the compound (oxide) therein a content of an Na compound (Na oxide) by Na₂O conversion of 10% to 30% (7 at. % to 20 at. % by Na conversion), and more preferably 15% to 25% (10 at. % to 16 at. %).

If the content of the alkali metal by compound (oxide: Na₂O) conversion is 10% to 30%, the composition of the silicate glass layer is not particularly limited and includes, for example, one or more than one type of alkali metal and/or alkali-earth metal. When the content of the alkali metal within the alkali supply layer 50 is less than 10%, the level of improvement of the conversion efficiency is low, even when the alkali metal is diffused into the photoelectric conversion layers 34. On the other hand, when the content of alkali metal within the alkali supply layer 50 exceeds 30%, it becomes difficult to manufacture the sputter target used to form the alkali supply layer 50. This is because the glass melting point decreases or composition irregularities occur.

When the alkali supply layer 50 is made of Mo that contains Na, for example, the Mo contains an Na compound such as NaF or Na₂MoO₄, with the content by Na conversion preferably being 3 at. % to 15 at. %, and more preferably 5 at. % to 10 at. %.

If the content of the alkali metal by Na conversion is 3 at. % to 15 at. %, the composition of the Mo containing Na is not particularly limited and includes, for example, one or more than one type of alkali metal and/or alkali-earth metal.

The alkali metal content (concentration) may be the content upon formation of the alkali supply layer 50, or the content upon formation of the photoelectric conversion element 40.

When the content of the alkali metal (Na) within the alkali supply layer 50 is less than 3 at. %, the amount of Na diffused within the CIGS photoelectric conversion layers 34 is low in the thin film range of the alkali supply layer 50, resulting in failure to achieve favorable photoelectric conversion characteristics. On the other hand, when the content of the alkali metal within the alkali supply layer 50 exceeds 15 at. %, uniform diffusion within the target and precipitation become problematic, making target manufacture difficult.

The reason for the preferred content range (5 at. % to 10 at. %) of alkali metal within the alkali supply layer 50 is that a low content results in failure to adequately supply Na to the photoelectric conversion layers 34 and, in turn, failure to achieve conversion efficiency, similar to the case of soda-lime glass (SLG), and a high content results in failure to achieve favorable content in the target and, in turn, failure to achieve a thin, quality film during film formation.

Exemplary alkali metals include Li, Na, K, Rb, and Cs. Exemplary alkali-earth metals include Be, Mg, Ca, Sr, and Ba. For reasons such as ease of achieving a chemically safe and easy-to handle compound, ease of discharge from the alkali supply layer 50 by heat, and a high crystallinity improvement effect of the photoelectric conversion layers 34, the alkali metal is preferably at least one kind selected from Na, K, Rb, and Cs, more preferably Na and/or K, and especially preferably Na. Thus, in the following, the alkali metal is mainly described using representative examples.

In this embodiment, the alkali supply layer 50 may comprise a soda-lime glass (SLG) having an alkali metal content of 10% to 30% by Na₂O conversion.

This soda-lime glass may comprise a composition having an alkali metal content of 15% by Na₂O conversion (10 at. % by Na conversion) as shown in Table 1 below. In such a case, the content (%) of alkali metal is the concentration of Na₂O that contains Na. The alkali metal content indicates the content in the compound If Na is a compound, but in this description indicates the Na₂O converted amount or the Na converted amount.

TABLE 1

| Component | Percentage (%) |
|---|---|
| SiO₂ | 72 |
| Na₂O | 15 |
| CaO | 7.2 |
| B₂O₃ | 4 |
| Al₂O₃ | 2 |
| Fe₂O₃ | 0.09 |
| TiO₂ | 0.002 |

When the Na content within the soda-lime glass shown in the above Table 1 increases or decreases, the amount of Na₂O increases or decreases, thereby increasing or decreasing the amount of SiO₂.

Further, when the soda-lime glass layer serving as the alkali supply layer 50 is formed, the formation method used can be an RF sputtering method or PVD method (physical vapor deposition method) such as vapor deposition method that employs the soda-lime glass as the vapor deposition source.

The alkali metal compound and alkali-earth metal compound included in the alkali supply layer 50 may be organic or inorganic compounds.

Exemplary alkali metal compounds include inorganic salts such as sodium fluoride, potassium fluoride, sodium sulfide, potassium sulfide, sodium selenide, potassium selenide, and sodium chloride, and potassium chloride; and organic salts such as potassium salt or sodium of an organic acid, such as a polyacid.

Further, exemplary alkali-earth metal compounds include inorganic salts such as calcium fluoride, magnesium fluoride, calcium sulfide, magnesium sulfide, and calcium selenide; and organic salts such as magnesium or calcium salts of an organic acid, such as a polyacid.

In this specification, the term “polyacid” includes heteropolyacids.

Additionally, since a thick alkali supply layer 50 makes the layers more susceptible to delamination, the alkali supply layer 50 preferably has a thickness of 100 nm to 800 nm, more preferably 100 nm to 400 nm.

Since this embodiment provides a diffusion prevention layer 52 made of a nitride, or in a case where the alkali supply layer 50 is made of soda-lime glass (SLG), the alkali metal content (concentration) of the alkali supply layer 50 is 10% to 30% by Na₂O conversion, making it possible to supply alkali metal to the photoelectric conversion layers 34 in an amount sufficient for improving the conversion efficiency, even if the thickness of the alkali supply layer 50 is a thin 100 nm to 800 nm. Thus, according to the present invention, it is possible to decrease the thickness of the alkali supply layer 50 and thus prevent the alkali supply layer 50 from becoming the origin of delamination, shorten the fabrication time of the alkali supply layer 50, and improve solar cell productivity.

Further, according to the present invention, it is possible to favorably and appropriately control the amount of alkali metal, such as Na, diffused from the alkali supply layer 50 to the photoelectric conversion layers 34 by the film thickness of the alkali supply layer 50.

The diffusion prevention layer 52 prevents the alkali metal contained in the alkali supply layer 50 from diffusing to the substrate 10, and increases the amount of alkali metal diffused to the photoelectric conversion layers 34.

While the diffusion prevention layer 52 needs to be made of a nitride, it is preferred that it is an insulator.

Specifically, the nitride that makes up the diffusion prevention layer 52 is preferably TiN (9.4×10⁻⁶/° C.), ZrN (7.2×10⁻⁶/° C.), BN (6.4×10⁻⁶/° C.), or AlN (5.7×10⁻⁶/° C.). Of these, the diffusion prevention layer 52 is preferably a material having a small difference in thermal expansion coefficient from that of the insulation layer 16 and aluminum anodized film of the substrate 10, and is thus more preferably made of ZrN, BN, or AlN. When a nitride, such as ZrN, BN, or AlN, having a small thermal expansion coefficient difference from the aluminum anodized film is used, it is possible to impart on the diffusion prevention layer 52 the function of a stress relaxation layer.

The insulators among these nitrides include BN and AlN and thus the diffusion prevention layer 52 is more preferably made of BN and AlN, and most preferably made of AlN, which has the lowest thermal expansion coefficient difference from the aluminum anodized film.

Thus, it is possible to uniform the thermal expansion coefficients of the diffusion prevention layer 52, the substrate 10, and the photoelectric conversion layers 34 and, in turn, maintain and improve the adhesion of the diffusion prevention layer 52, the substrate 10, and the photoelectric conversion layers 34, and prevent delamination of the substrate 10 and the photoelectric conversion layers 34.

It is believed that the diffusion prevention layer 52 made of a nitride film does not readily contain an alkali metal such as Na within the nitride film and thus prevents diffusion of alkali metal ions to the film interior, thereby promoting diffusion of the alkali metal from the alkali supply layer 50 to the upper layer and preventing diffusion of alkali metal ions to the substrate 10. As a result, the diffusion prevention layer 52 consisting of a nitride film should prevent diffusion of alkali metal ions supplied from the alkali supply layer 50 to the substrate 10 side, achieving an effect of diffusing the alkali metal to within the photoelectric conversion layers 34 (CIGS layers) of the back electrode layers 32. Therefore, even if the thickness of the alkali supply layer 50 is decreased taking into consideration delamination, the diffusion prevention layer 52 apparently needs to be made of a nitride in order to ensure that the amount of alkali metal diffused into the photoelectric conversion layers 34 (CIGS layers) is maintained at a predetermined level.

Thus, the diffusion prevention layer 52 should be capable of preventing the alkali metal from diffusing from the alkali supply layer 50 to the substrate 10 side, thereby preventing alteration caused by diffusion of an alkali metal, such as Na, into the insulation layer 16 made of an anodized film and, in turn, preventing delamination of the substrate 10 (metallic substrate 15) and photoelectric conversion layers 34.

The diffusion prevention layer 52 is preferably thick since increased thickness enhances its function of preventing diffusion into the substrate 10 and its function of increasing the amount of alkali metal diffused into the photoelectric conversion layers 34. Nevertheless, since a greater thickness causes the diffusion prevention layer 52 to become the origin of delamination, the diffusion prevention layer 52 preferably has a thickness of 10 nm to 200 nm, and more preferably 10 nm to 100 nm.

As described above, the diffusion prevention layer 52 is made of an insulator comprising a nitride, and therefore further improves the electrical insulation properties (withstand voltage characteristics) and heat resistance of the substrate 10 in addition to the insulation layer 16 of the substrate 10, making it possible to achieve a photoelectric conversion element 40 and solar cell 30 having high withstand voltage characteristics.

Next, the manufacturing method of the solar cell 30 of the embodiment under consideration will be described.

First, the substrate 10 formed as described above is prepared.

Next, a TiN film, ZrN film, BN film, or AlN film serving as the diffusion prevention layer 52 is formed by, for example, sputtering on the surface 16a of the insulation layer 16 of the substrate 10 using a film deposition apparatus.

Then, a soda-lime glass layer, with an alkali metal content of 10% to 30%, serving as the alkali supply layer 50 is formed by, for example, RF sputtering on the surface 52a of the diffusion prevention layer 52 using a film deposition apparatus.

Then, a molybdenum film serving as the back electrodes 32 is formed by, for example, sputtering on the surface 50a of the alkali supply layer 50 using a film deposition apparatus.

Then, for example, laser scribing is used to scribe the molybdenum film at a first predetermined position to form the separation grooves (P1) 33 extending in the width direction of the substrate 10. The back electrodes 32 separated from each other by the separation grooves (P1) 33 are thus formed.

Next, a CIGS layer, for example, serving as the photoelectric conversion layer 34 (p-type semiconductor layer), is formed by any one of the aforementioned film deposition methods using a film deposition apparatus so as to cover the back electrodes 32 and fill the separation grooves (P1) 33.

Then, a CdS layer (n-type semiconductor layer) serving as the buffer layer 36 is formed on the CIGS layer by, for example, chemical bath deposition (CBD) method. A p-n junction semiconductor layer is thus formed.

Next, laser scribing is used to scribe the molybdenum at a second position that differs from the first position of the separation grooves (P1) 33 to form the grooves (P2) 37 extending in the width direction of the substrate 10 to the back electrodes 32.

Then, a layer of ZnO doped with Al, B, Ga, Sb, and the like which serves as the transparent electrodes 38 is formed on the buffer layer 36 by sputtering or coating so as to fill the grooves (P2) 37.

Next, laser scribing is used to scribe the molybdenum at a third position that differs from the first position of the separation grooves (P1) 33 and the second position of the grooves (P2) 37 to form the opening grooves (P3) 39 extending in the width direction of the substrate 10 to the back electrodes 32. Thus, a plurality of power generating cells 54 are formed on the laminated body of the substrate 10, the diffusion prevention layer 52, and the alkali supply layer 50 to form the power generating layer 56.

Then, the photoelectric conversion elements 40 formed on the rightmost and leftmost back electrodes 32 in the longitudinal direction L of the substrate 10 are removed by, for example, laser scribing or mechanical scribing to expose the back electrodes 32. Then, the first conductive member 42 and the second conductive member 44 are connected by, for example, ultrasonic soldering onto the rightmost and leftmost back electrodes 32, respectively.

The solar cell 30 in which the plurality of photoelectric conversion elements 40 are connected in series can be thus manufactured as shown in FIG. 1.

If necessary, a bond/seal layer (not shown), a water vapor barrier layer (not shown), and a surface protection layer (not shown) are disposed on the top side of the resulting solar cell 30 and a bond/seal layer (not shown) and a back sheet (not shown) are formed on the back side of the solar cell 30, that is, on the back side of the substrate 10, and these layers are laminated and unified by vacuum lamination. A thin-film solar cell module can be thus achieved.

In this embodiment, the alkali supply layer 50 is provided, making it possible to appropriately supply alkali metal to the photoelectric conversion layer 34 (CIGS layer). The conversion efficiency of the photoelectric conversion elements 40 can be thus heightened and the photoelectric conversion elements 40 can be thus manufactured at a high yield.

Furthermore, the diffusion provision layer 52 is provided, making it possible to increase the amount of alkali metal diffused to the photoelectric conversion layers 34 and thus increase the amount of alkali metal supplied to the photoelectric conversion layers 34 and achieve the photoelectric conversion elements 40 having a more favorable conversion efficiency.

Further, the provision of the diffusion prevention layer 52 makes it possible to achieve a favorable conversion efficiency even if the alkali supply layer 50 is thin. In this embodiment, since the alkali supply layer 50 can be made thin, it is possible to shorten the fabrication time of the alkali supply layer 50 and improve the productivity of the photoelectric conversion element 40 and the solar cell 30. This also makes it possible to keep the alkali supply layer 50 from becoming the origin of delamination.

Further, in this embodiment, the substrate 10 serves as the substrate with an insulation layer comprising the metallic substrate 15, wherein the metal base 12 and the Al base 14 are laminated and unified, and the insulation layer 16 that is formed on the surface 14a of the Al base 14 of the metallic substrate 15, making it possible to maintain high insulation properties and high strength even when subjected to a film deposition process at a temperature of 500° C. or higher, for example, enabling manufacturing at a high temperature of 500° C. or higher. As a result, a compound semiconductor can be formed as the photoelectric conversion layer at 500° C. or higher. The compound semiconductor constituting the photoelectric conversion layer can improve the photoelectric conversion characteristics when formed at higher temperatures, and thus, in this way as well, it is possible to manufacture the photoelectric conversion element 40 having the photoelectric conversion layers 34 with improved photoelectric conversion characteristics.

Moreover, since the manufacturing process can be performed at a high temperature of 500° C. or higher, it is possible to eliminate restrictions on handling and the like during manufacturing.

As a result, the substrate 10 is imparted with excellent heat resistance, making it possible to achieve the solar cell 30 with excellent durability and an excellent storage life. A solar cell sub-module and solar cell module that have excellent durability and an excellent storage life can be thus achieved as well.

Furthermore, in this embodiment, the insulation layer 16 is formed and the diffusion prevention layer 52 is made of an insulator, making it possible to further improve the insulation properties (withstand voltage characteristics) of the substrate 10. Moreover, as described above, the substrate 10 exhibits excellent heat resistance. The solar cell 30 can thus exhibit even better durability and an even better storage life. This makes it possible to achieve a solar cell sub-module and solar cell module that exhibit even better durability and an even better storage life as well.

Further, in the embodiment, the substrate 10 is manufactured by a roll-to-roll process and therefore has flexibility. This makes it possible to manufacture the photoelectric conversion element 40 and the solar cell 30 while transporting the substrate 10 in the longitudinal direction L using a roll-to-roll process as well. With the solar cell 30 thus manufactured using an inexpensive roll-to-roll process, the cost of manufacturing the solar cell 30 can be reduced. This makes it possible to reduce the cost of the solar cell sub-module and solar cell module.

The present invention is basically as described above. While the photoelectric conversion element, thin-film solar cell, and photoelectric conversion element manufacturing method have been described above in detail, the present invention is by no means limited to the above embodiments, and various improvements or design modifications may be made without departing from the scope and spirit of the present invention.

### Example 1

The following specifically describes working examples of the photoelectric conversion element of the present invention.

In this example 1, working examples 1 to 6 and comparison examples 1 to 3 described below are manufactured and fabricated, the respective alkali metal content of the respective photoelectric conversion layers and the respective conversion efficiency of the photoelectric conversion elements are found and evaluated.

### Working Example 1

A metallic substrate was obtained by pressure bonding by a cold rolling process the commercial ferrite stainless steel material (material: SUS430) 12 and the aluminum material (hereinafter Al material) 14 having a high aluminum purity of 4N, and decreasing the thickness thereof to form a 3-layered clad material having a ferrite stainless steel thickness of 50 μm and an Al material thickness of 30 μm. The structure of this metallic substrate consisted of Al material (30 μm)/ferrite stainless steel material (50 μm)/and Al material (30 μm).

The stainless steel surface and end surface of this metallic substrate 15 was then covered by a masking film. Subsequently, the metallic substrate 15 thus covered was subjected to ultrasonic cleaning with ethanol, electrolytic polishing with an acetic acid+perchloric acid solution, and 40 V potentiostatic electrolysis in an 80 g/L oxalic acid solution to form an anodized film serving as the insulation layer 16, having a thickness of 10 μm, on the surface of the Al material 14. The thickness of the Al material 14 after anodization treatment was 15 μm. As a result of the above process, the substrate 10 with an insulation layer having the structure of an anodized film (10 μm)/Al material (15 μm)/ferrite stainless steel (50 μm)/Al material (15 μm)/anodized film (10 μm) was achieved.

Next, a film of aluminum nitride (AlN), serving as the diffusion prevention layer 52, was formed by reactive sputtering to a thickness of 100 nm on one side (the surface 16a of the insulation layer 16) of the substrate 10 with an insulation layer.

Then, a film of soda-lime glass (SLG), serving as the alkali supply layer 50 (Na supply source) was formed by RF sputtering to a thickness of 200 nm on the diffusion prevention layer 52. The content (Na concentration) of alkali metal in this SLG was 15% by Na₂O conversion (10 at. % by Na conversion).

Furthermore, a film of Mo, serving as the back electrodes 32, was formed by DC sputtering to a thickness of 800 nm on the alkali supply layer 50.

Then, a film of Cu(In_{0.7}Ga_{0.3})Se₂, serving as the photoelectric conversion layer (semiconductor layer) 34, was deposited on the Mo back electrodes 32 with the substrate temperature at 550° C.

The Cu(In_{0.7}Ga_{0.3})Se₂ film was formed to a thickness of 2 μm using K-Cells (Kundsen-Cells) as the vapor deposition source.

Then, the CdS buffer layer 36 was formed on the surface of the photoelectric conversion layer (CIGS layer) 34 to a thickness of 50 nm by a CBD method (chemical deposition method). Next, a ZnO layer (not shown) serving as a window layer was formed by sputtering to a thickness of 50 nm on the surface of the CdS buffer layer 36. Further, an Al—ZnO layer serving as the transparent electrode layer 38 was formed by sputtering to a thickness of 300 nm on the ZnO layer. Lastly, an Al layer (first and second conductive members 42 and 44) serving as collection electrodes was formed by vapor deposition on the surface of the Al—ZnO layer, i.e., the transparent electrode layer 38, thereby forming the photoelectric conversion element. The photoelectric conversion element thus formed served as working example 1.

### Working Example 2

A film of titanium nitride (TiN), serving as the diffusion prevention layer 52, was formed by reactive sputtering to a thickness of 100 nm on one side of the substrate 10 with an insulation layer using the same substrate 10 with an insulation layer as in working example 1.

Then, similar to the above working example 1, the alkali supply layer 50, the back electrodes 32, the photoelectric conversion layers 34, the buffer layers 36, the ZnO layer, the transparent electrode layer 38, and the collection electrodes (conductive members 42 and 44) were formed in that order on the diffusion prevention layer 52 to form the photoelectric conversion element. The photoelectric conversion element thus formed served as working example 2.

### Working Example 3

A film of zirconium nitride (ZrN), serving as the diffusion prevention layer, was formed by reactive sputtering to a thickness of 100 nm on one side of the substrate 10 with an insulation layer using the same substrate 10 with an insulation layer as in working example 1.

All other sections were formed in the same manner as the above working example 1 to form a photoelectric conversion element. The photoelectric conversion element thus formed served as working example 3.

### Working Example 4

A film of aluminum nitride (AlN), serving as the diffusion prevention layer 52, was formed by reactive sputtering to a thickness of 100 nm on one side of the substrate 10 with an insulation layer using the same substrate 10 with an insulation layer as in working example 1.

Then, a film of soda-lime glass (SLG), serving as the alkali supply layer 50 (Na supply source), was formed by RF sputtering to a thickness of 100 nm on the diffusion prevention layer 52 of the metal substrate 10 with an insulation layer. The content (Na concentration) of the alkali metal in this SLG was 15% by Na₂O conversion.

Then, similar to the above working example 1, the back electrodes 32, the photoelectric conversion layers 34, the buffer layers 36, the ZnO layer, the transparent electrode layer 38, and the collection electrodes (conductive members 42 and 44) were formed in that order on the alkali supply layer 50 to form the photoelectric conversion element. The photoelectric conversion element thus formed served as working example 4.

### Working Example 5

A film of aluminum nitride (AlN), serving as the diffusion prevention layer 52, was formed by reactive sputtering to a thickness of 100 nm on one side of the substrate 10 with an insulation layer using the same substrate 10 with an insulation layer as in working example 1.

Then, a film of soda-lime glass (SLG), serving as the alkali supply layer 50 (Na supply source), was formed by RF sputtering to a thickness of 300 nm on the diffusion prevention layer 52 of the metal substrate 10 with an insulation layer. The content (Na concentration) of the alkali metal in this SLG was 15% by Na₂O conversion.

Then, all other sections were formed in the same manner as the above working example 1 to form a photoelectric conversion element. The photoelectric conversion element thus formed served as working example 5.

### Working Example 6

A film of aluminum nitride (AlN), serving as the diffusion prevention layer 52, was formed by reactive sputtering to a thickness of 100 nm on one side of the substrate 10 with an insulation layer using the same substrate 10 with an insulation layer as in working example 1.

Then, a film of soda-lime glass (SLG), serving as the alkali supply layer 50 (Na supply source), was formed by RF sputtering to a thickness of 100 nm on the diffusion prevention layer 52 of the metal substrate 10 with an insulation layer. The content (Na concentration) of the alkali metal in this SLG was 15% by Na₂O conversion.

Furthermore, a film of Mo metal, serving as the back electrodes 32, was formed by DC sputtering to a thickness of 400 nm on the alkali supply layer 50.

Then, similar to the above working example 1, the photoelectric conversion layers 34, the buffer layers 36, the ZnO layer, the transparent electrode layer 38, and the collection electrodes (conductive members 42 and 44) were formed in that order on the back electrodes 32 to form the photoelectric conversion element. The photoelectric conversion element thus formed served as working example 6.

### Comparison Example 1

A soda-lime glass (SLG) film, serving as the alkali supply layer (Na supply source) 50, was formed by RF sputtering to a thickness of 200 nm on one side of the metal substrate 10 with an insulation layer without forming a diffusion prevention layer 52, using the same metal substrate 10 with an insulation layer as that in working example 1. The content (Na concentration) of the alkali metal in this SLG was 15% by Na₂O conversion.

Then, similar to the above working example 1, the back electrodes 32, the photoelectric conversion layers 34, the buffer layers 36, the ZnO layer, the transparent electrode layer 38, and the collection electrodes (conductive members 42 and 44) were formed in that order on the alkali supply layer 50 to form the photoelectric conversion element. The photoelectric conversion element thus formed served as comparison example 1.

### Comparison Example 2

A film of titanium oxide (TiO₂), serving as the diffusion prevention layer 52, was formed by reactive sputtering to a thickness of 100 nm on one side of the substrate 10 with an insulation layer using the same substrate 10 with an insulation layer as in working example 1.

Then, all other sections were formed in the same manner as the above working example 1 to form a photoelectric conversion element. The photoelectric conversion element thus formed served as comparison example 2.

### Comparison Example 3

A film of alumina (Al₂O₃), serving as the diffusion prevention layer 52, was formed by reactive sputtering to a thickness of 100 nm on one side of the substrate 10 with an insulation layer using the same substrate 10 with an insulation layer as in working example 1.

Then, all other sections were formed in the same manner as the above working example 1 to form a photoelectric conversion element. The photoelectric conversion element thus formed served as comparison example 3.

Table 2 shows the respective structures of the diffusion prevention layer and the respective structures and thicknesses of the alkali (Na) supply layer and lower (back) electrodes of the above working examples 1 to 6 and comparison examples 1 to 3.

In these examples, the alkali metal content (Na concentration) of the respective photoelectric conversion layer (CIGS layer) 34 of each of the photoelectric conversion elements of working examples 1 to 6 and comparison examples 1 to 3 was measured, and the nitride-induced diffusion prevention effect and rise in Na concentration within the CIGS photoelectric conversion layers were assessed in assessment 1.

The alkali metal content (Na concentration) was measured using SIMS (secondary ion mass spectrometry) given O₂⁺ as the primary ion type and 6.0 kV as the acceleration voltage for measurement. While the alkali metal content (Na concentration) within the photoelectric conversion layer (CIGS layer) 34 was distributed in the thickness direction, the mean value was derived through integration and this mean value was used to assess the content of the alkali metal (Na concentration). The results are shown in Table 2.

Further, the respective photoelectric conversion efficiencies of working examples 1 to 6 and comparison examples 1 to 3 were measured, and the increase in Na concentration and improvement in conversion efficiencies were assessed in assessment 2.

The fabricated photoelectric conversion elements were then assessed for photoelectric conversion efficiency using an artificial sun light of 100 mW/cm² and an air mass (AM) of 1.5.

Eight samples of each of the respective photoelectric conversion elements of working examples 1 to 6 and comparison examples 1 to 3 were fabricated. Then, the respective photoelectric conversion efficiencies of working examples 1 to 6 and comparison examples 1 to 3 were measured, and those having a photoelectric conversion efficiency of 80% or higher with respect to the maximum value were assessed as acceptable products, and all others as unacceptable products. The mean value of the acceptable products was then regarded as the conversion efficiency of the respective photoelectric conversion elements of working examples 1 to 6 and comparison examples 1 to 3. The results are shown in Table 2.

TABLE 2

| | | | | Na | |
|---|---|---|---|---|---|
| | Diffusion | Alkali | | Concentration | Conversion |
| | Prevention | Supply | Back | in CIGS | Efficiency |
| | Layer | Layer | Electrode | Layer (atoms/cm³) | (%) |
| Working | AlN | SLG: | Mo: 800 nm | 2 × 10¹⁹ | 16.8 |
| example 1 | | 200 nm | | | |
| Working | TiN | SLG: | Mo: 800 nm | 9 × 10¹⁸ | 16.2 |
| example 2 | | 200 nm | | | |
| Working | ZrN | SLG: | Mo: 800 nm | 9 × 10¹⁸ | 16.5 |
| example 3 | | 200 nm | | | |
| Working | AlN | SLG: | Mo: 800 nm | 7 × 10¹⁸ | 15.8 |
| example 4 | | 100 nm | | | |
| Working | AlN | SLG: | Mo: 800 nm | 3 × 10¹⁹ | 16.5 |
| example 5 | | 300 nm | | | |
| Working | AlN | SLG: | Mo: 400 nm | 1 × 10¹⁹ | 16.2 |
| example 6 | | 100 nm | | | |
| Comparison | None | SLG: | Mo: 800 nm | 9 × 10¹⁶ | 11.8 |
| example 1 | | 200 nm | | | |
| Comparison | TiO₂ | SLG: | Mo: 800 nm | 6 × 10¹⁷ | 12.4 |
| example 2 | | 200 nm | | | |
| Comparison | Al₂O₃ | SLG: | Mo: 800 nm | 3 × 10¹⁷ | 13.1 |
| example 3 | | 200 nm | | | |

As shown in Table 2 above, a comparison of working examples 1 to 6 and comparison example 1 first shows that those examples with a diffusion prevention layer have an increased Na concentration within the CIGS layer. Accordingly, the conversion efficiency shows improvement as well.

Next, a comparison of working examples 1 to 6 and comparison examples 2 and 3 reveals that those examples with a diffusion prevention layer made of a nitride have an increased Na concentration within the CIGS layer. From the above, it is understood that the diffusion prevention layer made of a nitride is more effective than a diffusion prevention layer made of an oxide. Presumably, while the oxide film prevents diffusion by including Na therein, the nitride does not readily contain an alkali metal such as Na within the film and thus inhibits diffusion to the nitride film interior, thereby promoting Na diffusion to the CIGS layer that is an upper layer above the alkali supply layer. Much of the Na is thus thought to be diffused to the upper CIGS layer.

Further, a comparison of working examples 1 to 3 does not reveal much of a difference between the examples. Of the nitrides that constitute the diffusion prevention layer, AlN, TiN, and ZrN all seem to have the same effects of preventing alkali metal diffusion to the substrate and diffusing Na to the CIGS layer.

Further, a comparison of working example 1 and working examples 4 to 6 reveals that, with an SLG layer (of the alkali supply layer or Na supply source) having a thickness of 200 nm, Na can be supplied to the CIGS layer and the conversion efficiency can be sufficiently improved. Further, from the results it is understood that even a thickness of 100 nm results in an adequate effect. Furthermore, the comparison shows that decreasing the thickness of the Mo film, which serves as the back electrodes, slightly increases the Na concentration within the CIGS layer.

The leakage current of the respective substrates of the photoelectric conversion elements of working example 1 and comparison example 1 were measured and the insulation properties of the respective substrates were assessed in assessment 3.

In the respective metal substrates 10 with an insulation layer of working example 1 and comparison example 1, Au electrodes of a diameter of 3.5 mm and a thickness of 0.2 μm were formed by mask vapor deposition on the AlN film (aluminum nitride film) serving as the diffusion prevention layer 52 in working example 1, and on the metal substrate 10 (anodized film) with an insulation layer in comparison example 1. Then, with the Au electrodes serving as a negative pole, a voltage of 200 V was applied between the metal substrate and Au electrodes, and the leakage current that flowed between the metal substrate and Au electrodes was measured at the time the voltage was applied. The leakage current density was then found by dividing the detected leakage current by the Au electrode surface area (9.6 mm²). This leakage current density was then used to assess the insulation properties.

Table 3 below shows the measurement results (leakage current densities) of the insulation properties of working example 1 and comparison example 1.

TABLE 3

| | Layer | Leakage Current |
|---|---|---|
| | Configuration | Density (μA/cm²) |
| Working example 1 | AlN/Substrate | 0.08 |
| Comparison example 1 | Substrate | 0.72 |

As shown in the results of the above Table 3, working example 1, which has the diffusion prevention layer 52 made of the insulator aluminum nitride, exhibits superior insulation properties.

### Example 2

In this example 2, working examples 10 to 23 and comparison examples 10 to 19 described below are fabricated, and the respective alkali metal content of the respective photoelectric conversion layers and the respective conversion efficiency of the photoelectric conversion elements are found and evaluated. Note that, in addition to the working examples 10 to 23 and the comparison examples 10 to 19, the examples disclosed in Applied Physics Letters, 93, 124105 (2008) are provided as comparison examples 20 to 25 for further comparison thereof.

### Working Example 10

The metallic substrate 15 was obtained by pressure bonding by a cold rolling process the commercial ferrite stainless steel material (material grade: SUS430) 12 and the aluminum material (hereinafter Al material) 14 having a high aluminum purity of 4N, and decreasing the thickness thereof to form a 3-layered clad material having a ferrite stainless steel thickness of 100 μm and an Al material thickness of 30 μm. The structure of this metallic substrate 15 consisted of Al material (30 μm)/ferrite stainless steel material (100 μm)/and Al material (30 μm).

The stainless steel surface and end surface of this metallic substrate 15 were then covered by a masking film. Subsequently, the metallic substrate 15 thus covered was subjected to ultrasonic cleaning with ethanol, electrolytic polishing with an acetic acid+perchloric acid solution, and 80 V potentiostatic electrolysis in a 1 M malonic acid solution at a temperature of 80° C. to form an anodized film serving as the insulation layer 16, having a thickness of 10 μm, on the surface of the Al material 14. The thickness of the Al material 14 after anodization treatment was 15 μm. As a result of the above process, the substrate 10 with an insulation layer having the structure of an anodized film (10 μm)/Al material (15 μm)/ferrite stainless steel (100 μm)/Al material (15 μm)/anodized film (10 μm) was achieved.

Next, a film of aluminum nitride (AlN), serving as the diffusion prevention layer 52, was formed by reactive sputtering to a thickness of 100 nm on the surface 16a of the insulation layer 16 of the substrate 10 with an insulation layer. Subsequently, a film of soda-lime glass (SLG), serving as the alkali supply layer 50 (Na supply source), was formed by RF sputtering to a thickness of 100 nm on the diffusion prevention layer 52 to obtain a soda-lime glass layer (hereinafter “SLG layer”). The content of the alkali metal (Na concentration) of this SLG layer is 10 at. %.

Furthermore, a Mo film, serving as the back electrodes 32, was formed by DC sputtering to a thickness of 600 nm on the alkali supply layer 50.

Next, Cu(In_{0.7}Ga_{0.3})Se₂, serving as the photoelectric conversion layer 34, was formed to a thickness of 2 μm on the back electrodes 32 at a substrate temperature of 520° C., using a vapor deposition method that employs K cells as the vapor deposition source.

Then, on the front surface of the photoelectric conversion layer 34, the CdS buffer layer 36 was formed by CBD method to a thickness of 50 nm. Next, an Al—ZnO layer, serving as the transparent electrode layer 38, was formed by sputtering to a thickness of 200 nm on the surface of the CdS buffer layer 36. Lastly, an Al layer (first and second conductive members 42 and 44) serving as collection electrodes was formed by vapor deposition on top of the Al—ZnO layer, i.e., the transparent electrode layer 38, thereby forming the photoelectric conversion element. The photoelectric conversion element thus formed served as working example 10.

Note that, according to this example, the SLG layer serving as the alkali supply layer 50 was formed under deposition conditions including an 8-inch diameter target size for the soda lime glass, a power density of 2 W/cm², and a deposition pressure of 1.2 Pa (Ar+O₂ atmosphere), using an RF power source. In this case, the deposition rate was 4 nm/minute.

On the other hand, when an Mo film formed as the back electrodes 32 was formed under deposition conditions including an 8-inch diameter target size, a power density of 7 W/cm², and a deposition pressure of 0.5 Pa (Ar atmosphere) using a pulse DC power source, the deposition rate was 300 nm/minute. The SLG layer formed as the alkali serving layer exhibited a deposition rate of approximately 1/75 of that of the Mo layer.

### Working Examples 11 to 14

Working examples 11 to 14, in comparison with working example 10, have the same configuration as working example 10 other than a different SLG layer (alkali supply layer) thickness.

Working example 11 has an SLG layer thickness of 150 nm, working example 12 has an SLG layer thickness of 200 nm, working example 13 has an SLG layer thickness of 250 nm, and working example 14 has an SLG layer thickness of 300 nm.

### Comparison Examples 10 to 14

Comparison example 10, in comparison with working example 10, has the same configuration as working example 10 other than the absence of an aluminum nitride layer (hereinafter “AlN layer”) serving as the diffusion prevention layer 52.

In addition, comparison examples 11 to 14 each have the same configuration as comparison example 10 other than a different SLG layer (alkali supply layer) thickness.

Comparison example 11 has an SLG layer thickness of 150 nm, comparison example 12 has an SLG layer thickness of 200 nm, comparison example 13 has an SLG layer thickness of 250 nm, and comparison example 14 has an SLG layer thickness of 300 nm.

### Working Example 15

Working example 15 uses the metallic substrate 15 having a configuration comprising Al material (30 μm)/ferrite stainless steel (100 μm)/Al material (30 μm, similar to working example 10.

In working example 15, the stainless steel surface and end surface of the metallic substrate 15 were covered by a masking film. Subsequently, the metallic substrate 15 thus covered was subjected to ultrasonic cleaning with ethanol, electrolytic polishing with an acetic acid+perchloric acid solution, and 40 V potentiostatic electrolysis in a 0.5 M oxalic acid solution at a temperature of 16° C. to form an anodized film serving as the insulation layer 16, having a thickness of 10 μm, on the surface of the Al material 14. The thickness of the Al material 14 after anodization was 15 μm. As a result of the above process, the substrate 10 with an insulation layer having the structure of an anodized film (10 μm)/Al material (15 μm)/ferrite stainless steel (100 μm)/Al material (15 μm)/anodized film (10 μm) was achieved.

Next, an AlN layer serving as the diffusion prevention layer 52 was formed to a thickness of 100 nm on the surface 16a of the insulation layer 16 of the substrate 10 with an insulation layer. Subsequently, an SLG layer was formed by RF sputtering to a thickness of 100 nm on the diffusion prevention layer 52. The content of the alkali metal (Na concentration) of this SLG layer is 10 at. %.

Furthermore, a Mo film, serving as the back electrodes 32, was formed by DC sputtering to a thickness of 600 nm on the alkali supply layer 50.

Next, Cu(In_{0.7}Ga_{0.3})Se₂, serving as the photoelectric conversion layer 34, was formed to a thickness of 2 μm on the back electrodes 32 at a substrate temperature of 520° C., using a vapor deposition method that employs K cells as the vapor deposition source.

Then, on the front surface of the photoelectric conversion layer 34, the CdS buffer layer 36 was formed by CBD method to a thickness of 50 nm. Next, an Al—ZnO layer, serving as the transparent electrode layer 38, was formed by sputtering to a thickness of 200 nm on the surface of the CdS buffer layer 36. Lastly, an Al layer (first and second conductive members 42 and 44) serving as collection electrodes was formed by vapor deposition on top of the transparent electrode layer 38, thereby forming the photoelectric conversion element. The photoelectric conversion element thus formed served as working example 15.

### Working Examples 16 to 19

Working examples 16 to 19, in comparison with working example 15, have the same configuration as working example 15 other than a different SLG layer (alkali supply layer) thickness.

Working example 16 has an SLG layer thickness of 150 nm, working example 17 has an SLG layer thickness of 200 nm, working example 18 has an SLG layer thickness of 250 nm, and working example 19 has an SLG layer thickness of 300 nm.

### Comparison Examples 15 to 19

Comparison example 15, in comparison with working example 15, has the same configuration as working example 15 other than the absence of an AlN layer serving as the diffusion prevention layer 52.

In addition, comparison examples 16 to 19 each have the same configuration as comparison example 15 other than a different SLG layer (alkali supply layer) thickness.

Comparison example 16 has an SLG layer thickness of 150 nm, comparison example 17 has an SLG layer thickness of 200 nm, comparison example 18 has an SLG layer thickness of 250 nm, and comparison example 19 has an SLG layer thickness of 300 nm.

### Working Example 20

Working example 20, in comparison with working example 15, has the same configuration as working example 15 other than formation of a 100 nm thick titanium nitride layer (TiN layer) rather than an AlN layer as the diffusion prevention layer 52 and a 200 nm thick SLG layer.

### Working Example 21

Working example 21, in comparison with working example 15, has the same configuration as working example 15 other than formation of a 100 nm thick zirconium nitride layer (ZrN layer) rather than an AlN layer as the diffusion prevention layer 52 and a 200 nm thick SLG layer.

### Working Example 22

Working example 22, in comparison with working example 15, has the same configuration as working example 15 other than formation of a 100 nm thick titanium oxide layer (TiO₂ layer) rather than an AlN layer as the diffusion prevention layer 52 and a 200 nm thick SLG layer.

### Working Example 23

Working example 23, in comparison with working example 15, has the same configuration as working example 15 other than formation of a 100 nm thick alumina layer (Al₂O₃ layer) rather than an AlN layer as the diffusion prevention layer 52 and a 200 nm thick SLG layer.

### Comparison Examples 20 to 25

Comparison examples 20 to 25 are the examples disclosed in Applied Physics Letters, 93, 124105 (2008). To clearly indicate that these examples are those disclosed in Applied Physics Letters, 93, 124105 (2008), comparison example 20 to 25 in Table 4 are marked with “*Literature” in the “Remarks” column.

In comparison example 20, a Ti foil substrate having a thickness of 20 μm was used, and an Mo layer serving as back electrodes was formed by sputtering to a thickness of 800 nm on this Ti foil substrate. On the back electrodes, Cu(In,Ga)Se₂ serving as the photoelectric conversion layer 34 was formed using the three-stage method. Note that the deposition temperature of Cu(In,Ga)Se₂ was 350° C. in the first stage and 550° C. in the second and third stages.

Comparison example 21, in comparison with comparison example 20, has the same configuration as comparison example 20 other than formation of a 50 nm thick SLG layer as the alkali supply layer on the Ti foil substrate.

Comparison example 22, in comparison with comparison example 20, has the same configuration as comparison example 20 other than formation of a 120 nm thick SLG layer on the Ti foil substrate.

Comparison example 23, in comparison with comparison example 20, has the same configuration as comparison example 20 other than formation of a 150 nm thick SLG layer on the Ti foil substrate.

Comparison example 24, in comparison with comparison example 20, has the same configuration as comparison example 20 other than formation of a 230 nm thick SLG layer on the Ti foil substrate.

Comparison example 25, in comparison with comparison example 20, has the same configuration as comparison example 20 other than its 50-micrometer zirconia substrate, and formation of a 100 nm thick SLG layer on this zirconia substrate.

In this example 2, the alkali metal content (Na concentration) values of the respective photoelectric conversion layers (CIGS layers) 34 of the photoelectric conversion elements of working examples 10 to 23 and comparison examples 10 to 19 were measured, and the nitride-induced diffusion prevention effect and rise in Na concentration within the CIGS photoelectric conversion layers were assessed in assessment 1 in the same manner as the above example 1.

The alkali metal content (Na concentration) was measured using SIMS (secondary ion mass spectrometry) given O₂⁺ as the primary ion type and 6.0 kV as the acceleration voltage for measurement. While the alkali metal content (Na concentration) within the photoelectric conversion layers (CIGS layers) 34 is distributed in the thickness direction, the mean value was derived through integration and this mean value was used to assess the content (Na concentration) of the alkali metal. The results are shown in Table 4.

The respective photoelectric conversion efficiencies of each of the photoelectric conversion elements of working examples 10 to 23 and comparison examples 10 to 19 were measured, and the increase in Na concentration and improvement in conversion efficiencies of working examples 10 to 23 and comparison examples 10 to 19 were assessed in assessment 2.

The fabricated photoelectric conversion elements were then assessed for photoelectric conversion efficiency using an artificial sun light of 100 mW/cm² and an air mass (AM) of 1.5.

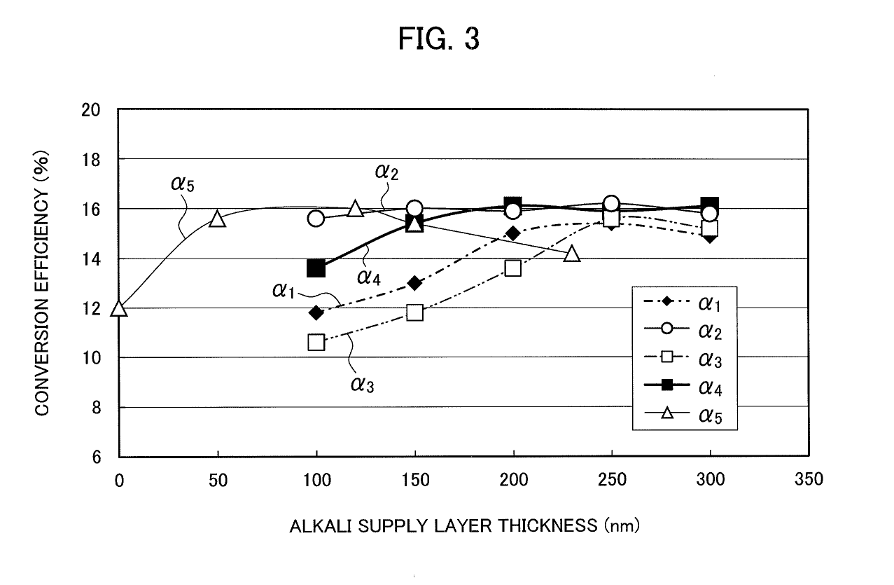

Eight samples of each of the respective photoelectric conversion elements of working examples 10 to 23 and comparison examples 10 to 19 were fabricated. Then, the respective photoelectric conversion efficiencies of working examples 10 to 23 and comparison examples 10 to 19 were measured, and those photoelectric conversion elements having a photoelectric conversion efficiency of 80% or higher with respect to the maximum value were assessed as acceptable products, and all others as unacceptable products. The mean value of the acceptable products was then regarded as the conversion efficiency of the respective photoelectric conversion elements of working examples 10 to 23 and comparison examples 10 to 19. The results are shown in Table 4 and FIG. 3.

Note that the more than half of the eight samples of photoelectric conversion elements thus fabricated that were assessed as unacceptable are marked by an asterisk (*) in Table 4.

Further, the respective photoelectric conversion efficiencies of comparison examples 20 to 25 were measured under the conditions of a 1.5 air mass (AM) and 100 mW/cm², as indicated in Applied Physics Letters, 93, 124105 (2008). The results of comparison examples 20 to 25 are also indicated in Table 4 and FIG. 3 below.

In FIG. 3, α₁ is the plotted curve corresponding to comparison examples 10 to 14, α₂ is the plotted curve corresponding to working examples 10 to 14, α₃ is the plotted curve corresponding to comparison examples 15 to 19, α₄ is the plotted curve corresponding to working examples 15 to 19, and α₅ is the plotted curve corresponding to comparison examples 20 to 24.

TABLE 4

| | | Diffusion | Alkali | | Na Concentration | Conversion | |
|---|---|---|---|---|---|---|---|
| | Electrolytic | Prevention | Supply | Back | of CIGS Layer | Efficiency | |
| | Solution | Layer | Layer | Electrode | (atoms/cm³) | (%) | Remarks |
| Working | Malonic acid | AlN | 100 nm | Mo: 600 nm | 7 × 10⁸ | 15.6 | |
| example 10 | | | | | | | |
| Working | Malonic acid | AlN | 150 nm | Mo: 600 nm | 8 × 10¹⁸ | 16.0 | |
| example 11 | | | | | | | |
| Working | Malonic acid | AlN | 200 nm | Mo: 600 nm | 1 × 10¹⁹ | 15.9 | |
| example 12 | | | | | | | |
| Working | Malonic acid | AlN | 250 nm | Mo: 600 nm | 3 × 10¹⁹ | 16.2 | |
| example 13 | | | | | | | |
| Working | Malonic acid | AlN | 300 nm | Mo: 600 nm | 3 × 10¹⁹ | 15.8 | |
| example 14 | | | | | | | |
| Comparison | Malonic acid | None | 100 nm | Mo: 600 nm | 5 × 10¹⁷ | 11.8 | |
| example 10 | | | | | | | |
| Comparison | Malonic acid | None | 150 nm | Mo: 600 nm | 1 × 10¹⁸ | 13.0 | |
| example 11 | | | | | | | |
| Comparison | Malonic acid | None | 200 nm | Mo: 600 nm | 6 × 10¹⁸ | 15.0 | |
| example 12 | | | | | | | |
| Comparison | Malonic acid | None | 250 nm | Mo: 600 nm | 9 × 10¹⁸ | 15.4 | |
| example 13 | | | | | | | |
| Comparison | Malonic acid | None | 300 nm | Mo: 600 nm | 2 × 10¹⁹ | 14.9 | * |
| example 14 | | | | | | | |
| Working | Oxalic acid | AlN | 100 nm | Mo: 600 nm | 2 × 10¹⁸ | 13.6 | |
| example 15 | | | | | | | |
| Working | Oxalic acid | AlN | 150 nm | Mo: 600 nm | 5 × 10¹⁸ | 15.4 | |
| example 16 | | | | | | | |
| Working | Oxalic acid | AlN | 200 nm | Mo: 600 nm | 1 × 10¹⁹ | 16.1 | |
| example 17 | | | | | | | |
| Working | Oxalic acid | AlN | 250 nm | Mo: 600 nm | 3 × 10¹⁹ | 15.9 | |
| example 18 | | | | | | | |
| Working | Oxalic acid | AlN | 300 nm | Mo: 600 nm | 1 × 10¹⁹ | 16.1 | |
| example 19 | | | | | | | |
| Working | Oxalic acid | TiN | 200 nm | Mo: 600 nm | 6 × 10¹⁸ | 15.2 | |
| example 20 | | | | | | | |
| Working | Oxalic acid | ZrN | 200 nm | Mo: 600 nm | 1 × 10¹⁹ | 16.1 | |
| example 21 | | | | | | | |
| Working | Oxalic acid | TiO₂ | 200 nm | Mo: 600 nm | 2 × 10¹⁸ | 13.8 | |
| example 22 | | | | | | | |
| Working | Oxalic acid | Al₂O₃ | 200 nm | Mo: 600 nm | 3 × 10¹⁸ | 12.9 | |
| example 23 | | | | | | | |
| Comparison | Oxalic acid | None | 100 nm | Mo: 600 nm | 2 × 10¹⁷ | 10.6 | |
| example 15 | | | | | | | |
| Comparison | Oxalic acid | None | 150 nm | Mo: 600 nm | 7 × 10¹⁷ | 11.8 | |
| example 16 | | | | | | | |
| Comparison | Oxalic acid | None | 200 nm | Mo: 600 nm | 3 × 10¹⁸ | 13.6 | |
| example 17 | | | | | | | |
| Comparison | Oxalic acid | None | 250 nm | Mo: 600 nm | 7 × 10¹⁸ | 15.6 | |
| example 18 | | | | | | | |
| Comparison | Oxalic acid | None | 300 nm | Mo: 600 nm | 1 × 10¹⁹ | 15.2 | * |
| example 19 | | | | | | | |
| Comparison | None | None | — | Mo: 800 nm | — | 12.0 | *Literature |
| example 20 | | | | | | | |
| Comparison | None | None | 50 nm | Mo: 800 nm | — | 15.6 | *Literature |
| example 21 | | | | | | | |
| Comparison | None | None | 120 nm | Mo: 800 nm | — | 16.0 | *Literature |
| example 22 | | | | | | | |
| Comparison | None | None | 150 nm | Mo: 800 nm | — | 15.4 | *Literature |
| example 23 | | | | | | | |
| Comparison | None | None | 230 nm | Mo: 800 nm | — | 14.2 | *Literature |
| example 24 | | | | | | | |
| Comparison | None | None | 100 nm | Mo: 800 nm | 1 × 10¹⁹ units | 15.9 | *Literature |
| example 25 | | | | | | | |

As shown in the above Table 4 and in FIG. 3, the conversion efficiency improvement effect is not evident when an alkali supply layer of a certain thickness is non-existent.

Furthermore, the substrates with an insulation layer (anodized substrate) indicated by α₁ to α₄ (working examples 10 to 19 and comparison examples 10 to 19) require an alkali supply layer that is thicker than the metal substrate indicated by α₅ (comparison examples 20 to 24).

In addition, the substrates with an insulation layer treated with oxalic acid [α₃ (comparison examples 15 to 19) and α₄ (working examples 15 to 19)] require an alkali supply layer that is thicker than the substrates with an insulation layer treated with malonic acid [α₁ (comparison examples 10 to 14) and α₂ (working examples 10 to 14)].

Note that, as in comparison example 14 and comparison example 19 which have a 300 nm thick alkali supply layer in Table 4, a thicker alkali supply layer appears to cause film alterations from the reaction between the alkali elements and anodized film, resulting in delamination and cracking and thus an increase in element abnormalities.

Further, upon comparison of the examples having the same electrolytic solution but differences in the presence or non-presence of a diffusion prevention layer, it is clear that the provision of a diffusion prevention layer in α₁ and α₂, as well as α₃ and α₄ makes it possible to reduce the thickness of the alkali supply layer for improving conversion efficiency. With the thickness of the alkali supply layer having a low deposition rate thus reduced, productivity can be improved. Furthermore, since diffusion of the alkali elements into the substrate with an insulation layer is suppressed by the diffusion prevention layer, it is possible to suppress film alternations caused by the reaction between the alkali elements and the anodized film and, in turn, suppress the delamination of the substrate with an insulation layer caused by film alterations.

Further, samples 1 to 6 shown in Table 5 below were fabricated and subsequently assessed in terms of diffusion prevention layer performance, revealing that the diffusion prevention layer was preferably nitride, and more preferably AlN or ZrN.

First, for samples 3 to 6, soda-lime glass substrates were prepared and, on these substrates, AlN, ZrN, TiN, and TiO₂ films, serving as diffusion prevention layers, were respectively formed. Deposition was performed by reactive sputtering, and each film thickness was adjusted to 300 nm.

In addition, samples (samples 1 and 2) without a diffusion prevention layer were also prepared as comparison examples.

An Mo electrode layer serving as the back electrodes was then formed by DC sputtering to a thickness of 1 μm on each of the samples 1 to 6.

The substrates comprising the Mo electrode layer of samples 2 to 6 and not of sample 1 were then placed in a vacuum heating furnace and heat-treated for 30 minutes at a temperature of 550° C. to diffuse the Na from the substrate into the respective back electrodes (Mo electrode layer) of each of the samples 2 to 6. Note that sample 1 was not heat-treated and was used for basal value measurement as a case where diffusion processing was not performed.

Subsequently, each of the substrates of samples 1 to 6 was subjected to SIMS analysis to make the Na concentration within the back electrodes (Mo electrode layer) equal to a predetermined value. The results are shown in Table 5 below.

TABLE 5

| | | | | | Na Concentration |
|---|---|---|---|---|---|
| | | Diffusion | | | (atoms/cm³) in Back |
| | | Prevention | Back | Heat | Electrode (Mo |
| | Substrate | Layer | Electrode | Treatment | Electrode Layer) |
| Sample 1 | SLG | None | Mo: 1 μm | None | 9 × 10¹⁶ |
| Sample 2 | SLG | None | Mo: 1 μm | 550° C., 30 | 5 × 10²⁰ |
| | | | | minutes | |
| Sample 3 | SLG | AlN: 300 nm | Mo: 1 μm | 550° C., 30 | 4 × 10¹⁸ |
| | | | | minutes | |
| Sample 4 | SLG | ZrN: 300 nm | Mo: 1 μm | 550° C., 30 | 4 × 10¹⁸ |
| | | | | minutes | |
| Sample 5 | SLG | TiN: 300 nm | Mo: 1 μm | 550° C., 30 | 8 × 10¹⁹ |
| | | | | minutes | |
| Sample 6 | SLG | TiO₂: 300 nm | Mo: 1 μm | 550° C., 30 | 1 × 10²⁰ |
| | | | | minutes | |

The diffusion prevention results achieved by oxide and nitride with respect to diffusion into the alkali back electrodes (Mo electrode layer) were confirmed as shown in the above Table 5. Of the different materials, AlN and ZrN exhibited a high diffusion prevention effect. The reason the Na concentration within the back electrodes (Mo electrode layer) of samples 3 to 6 comprising the diffusion prevention layer is high compared to sample 1 (comparison sample), which was not heat-treated, is presumably that the Na emitted into the air diffused from the Mo film surface without passing from the substrate through the diffusion prevention layer.

Furthermore, the surface state of the substrate 10 with an insulation layer, Ti foil substrate, and zirconia substrate used in this example 2 was examined. The results are shown in Table 6.

Note that the pore size and wall thickness indicated in Table 6 are values found by observing the anodized film using a scanning electron microscope, and measuring and calculating the average of the values of 20 cells formed in the anodized film. Further, the void percentage indicates the pore surface area as a percentage of the film surface area. The Ti foil substrate and the zirconia substrate, without an anodized film or the like, were given a pore size and wall thickness of “None” and a void percentage of “0%” since the surfaces thereof are not porous in structure.

As shown in Table 6, alkali diffuses more readily toward the substrate, i.e., alkali tends to be drawn toward the substrate, as the surface area of the substrate increases.

TABLE 6

| | | | Ti Foil |
|---|---|---|---|
| | Oxalic Acid | Malonic Acid | Substrate, |
| | Treated | Treated | Zirconia |
| | Substrate | Substrate | Substrate |
| Pore size | 30 nm | 60 nm | None |
| Wall | 70 nm | 140 nm | None |
| thickness | | | |
| Void | 8% | 8% | 0% |
| percentage | | | |
| Surface | Large | Medium | Small |
| area | | | |

What is claimed is:

1. A photoelectric conversion element comprising:
a substrate with an insulation layer comprising a metallic substrate and an electrical insulation layer formed on a surface of said metallic substrate;
a diffusion prevention layer made of nitride and formed on said electrical insulation layer;
an alkali supply layer containing an alkali metal element or an alkaline-earth metal element and formed on said diffusion prevention layer;
a lower electrode formed on said alkali supply layer;
a photoelectric conversion layer comprising a compound semiconductor layer and formed on said lower electrode; and
an upper electrode formed on said photoelectric conversion layer,
wherein said electrical insulation layer comprises an anodized film of aluminum, and said diffusion prevention layer prevents at least diffusion of the alkali metal element or the alkaline-earth metal element from said alkali supply layer to said substrate with the insulation layer.

2. The photoelectric conversion element according to claim 1, wherein said compound semiconductor comprises at least one kind of compound semiconductor of a chalcopyrite structure.

3. The photoelectric conversion element according to claim 2, wherein said compound semiconductor is composed of at least one kind of compound semiconductor comprising a group Ib element, a group IIIb element, and a group VIb element.

4. The photoelectric conversion element according to claim 3, wherein said group Ib element is composed of at least one selected from the group consisting of Cu and Ag, said group IIIb element is composed of at least one selected from the group consisting of Al, Ga, and In, and said group VIb element is composed of at least one selected from the group consisting of S, Se, and Te.

5. The photoelectric conversion element according to claim 1, wherein said nitride is an electrical insulator.

6. The photoelectric conversion element according to claim 5, wherein said nitride comprises at least one of TiN, ZrN, BN, and AlN.

7. The photoelectric conversion element according to claim 6, wherein said nitride is composed of AlN.

8. The photoelectric conversion element according to claim 1, wherein said diffusion prevention layer has a thickness of 10 nm to 200 nm.

9. The photoelectric conversion element according to claim 8, wherein said thickness of said diffusion prevention layer ranges from 10 nm to 100 nm.

10. The photoelectric conversion element according to claim 1, wherein said photoelectric conversion layer is split into plural elements by plural opening grooves, and said plural elements is electrically connected in series.

11. The photoelectric conversion element according to claim 1, wherein said alkali supply layer comprises a layer that supplies Na.

12. The photoelectric conversion element according to claim 1, wherein said alkali supply layer comprises a silicate glass layer having 7 at. % to 20 at. % in terms of Na.

13. The photoelectric conversion element according to claim 1, wherein said alkali supply layer comprises a layer formed by sputtering.

14. The photoelectric conversion element according to claim 1, wherein said alkali supply layer has a thickness of 100 nm to 800 nm.

15. The photoelectric conversion element according to claim 1, wherein said lower electrode is made of Mo, and has a thickness of 200 nm to 600 nm.

16. The photoelectric conversion element according to claim 15, wherein said thickness of said lower electrode ranges from 200 nm to 400 nm.

17. The photoelectric conversion element according to claim 1, wherein said metallic substrate comprises a laminated plate wherein a metal base and an Al base are laminated and unified.

18. The photoelectric conversion element according to claim 17, wherein said laminated plate laminates and integrates said metal base and said Al base by compression bonding.

19. The photoelectric conversion element according to claim 17, wherein said metal base comprises a steel material, an alloy steel material, a Ti foil, or a dual-layer base composed of the Ti foil and the steel material.

20. The photoelectric conversion element according to claim 19, wherein said alloy steel material is made of carbon steel or ferrite stainless steel.

21. The photoelectric conversion element according to claim 17, wherein a difference between a linear thermal expansion coefficient of said metal base and that of said photoelectric conversion layer is less than 3×10⁻⁶/° C.

22. The photoelectric conversion element according to claim 21, wherein said difference between the linear thermal expansion coefficient of said metal base and that of said photoelectric conversion layer is less than 1×10⁻⁶/° C.

23. The photoelectric conversion element according to claim 1, wherein said metallic substrate comprises a laminated plate wherein an alloy steel material made of ferrite stainless steel or carbon steel is integrated with an Al base by compression bonding, said lower electrode is made of Mo, and said photoelectric conversion layer is a layer comprising as a main component at least one kind of compound semiconductor comprising a group Ib element, a group IIIb element, and a group VIb element.

24. The photoelectric conversion element according to claim 1, wherein said anodized film has a porous structure.

25. A thin-film solar cell comprising the photoelectric conversion element according to claim 1.

26. A method of manufacturing a photoelectric conversion element, comprising:
forming an anodized film of aluminum as an electrical insulation layer on a surface of a metallic substrate to obtain a substrate with an insulation layer;
forming a diffusion prevention layer made of nitride on said electrical insulation layer of said substrate with the insulation layer;
forming an alkali supply layer containing an alkali metal element or an alkaline-earth metal element on said diffusion prevention layer;
forming a lower electrode on said conductive alkali supply layer;
forming a photoelectric conversion layer composed of a compound semiconductor on said lower electrode; and
forming an upper electrode on said photoelectric conversion layer,
wherein said diffusion prevention layer prevents diffusion of the alkali metal element or the alkaline-earth metal element from said alkali supply layer to said substrate with the insulation layer.

27. The manufacturing method according to claim 26, wherein
said metallic substrate is a laminated plate wherein a metal base and an Al base are laminated and unified, and
said forming step of said electrical insulation layer is a step of subjecting said Al base to an anodizing treatment to form an anodized film on a surface of said Al base.
